(19) United States
(12) Patent Application Publication
(10) Pub. No.: US 2025/0105038 A1
(43) Pub. Date: Mar. 27, 2025

(54) SUBSTRATE TRANSFER APPARATUS, SUBSTRATE PROCESSING APPARATUS, AND SUBSTRATE PROCESSING SYSTEM

(71) Applicant: SCREEN Holdings Co., Ltd., Kyoto (JP)

(72) Inventor: Yuichi TAKAYAMA, Kyoto (JP)

(21) Appl. No.: 18/892,079

(22) Filed: Sep. 20, 2024

(30) Foreign Application Priority Data
Sep. 21, 2023 (JP) 2023-155676

(51) Int. Cl. H01L 21/67; B65G 47/90; H01L 21/673; H01L 21/687

(52) U.S. Cl. CPC H01L 21/67259; B65G 47/905; H01L 21/67294; H01L 21/6732; H01L 21/68707

(57) ABSTRACT

A substrate transfer apparatus includes: a hand that holds and transfers a plurality of substrates by one by one from a carrier that stores the substrates in horizontal postures, with a predetermined interval between the substrates in a vertical direction; a receiving unit that receives substrate information corresponding to each of the substrates held by the carrier; and a control unit that controls the hand, the control unit is enabled to change a transfer operation of the hand, for each of the substrates, based on the substrate information.

This application claims priority to Japanese Patent Application No. 2023-155676 filed on Sep. 21, 2023, the subject matter of which is incorporated herein by reference in entirety.

### BACKGROUND OF THE INVENTION

### Field of the Invention

The present invention relates to a substrate transfer apparatus, a substrate processing apparatus, and a substrate processing system for transferring various types of substrates such as a semiconductor substrate, a substrate for a flat panel display (FPD) including a liquid crystal display and an organic electroluminescence (EL) display device, a glass substrate for a photomask, and a substrate for an optical disk.

### Description of the Related Art

The substrate processing apparatus described in JP 2021-48359 A includes a barcode reader. The barcode reader reads a barcode attached on a carrier, and outputs the detection result to a control unit. The control unit then determines the shape of the substrate, on the basis of the detection result of the barcode reader.

### List of Documents

JP2021-48359 A

In such a conventional substrate transfer apparatus, there is a disadvantage that a control mode can only be changed for the entire carrier, and substrates cannot be transferred appropriately when different types of substrates are stored in the one carrier.

### SUMMARY OF THE INVENTION

The present invention has been made in view of the situation described above, and an object of the present invention is to provide a substrate transfer apparatus, a substrate processing apparatus, and a substrate processing system capable of setting appropriately, when substrates in one carrier are to be transferred, a substrate transfer mode for each of such substrates.

In order to address the disadvantage described above, the present invention has the following configuration.

In other words, the present invention is a substrate transfer apparatus including:
a hand that holds and transfers a plurality of substrates one by one from a carrier that stores the substrates in horizontal postures, with a predetermined interval between the substrates in a vertical direction;
a receiving unit that receives substrate information corresponding to each of the substrates held in the carrier; and
a control unit that controls the hand, wherein
the control unit is enabled to change a transfer operation of the hand, for each of the substrates, based on the substrate information.

[Operation and Effect] The substrate transfer apparatus described above receives substrate information corresponding to each of the substrates held in the carrier. The substrate information includes information corresponding to each of the substrate. The substrate transfer apparatus described above changes the transfer operation of the hand for each of the substrates, on the basis of the substrate information. With this configuration, even when different types of substrates are stored in the carrier, the hand can be controlled appropriately on the basis of the substrate information. As a result, it becomes possible to transfer a substrate using a transfer operation suitable for the substrate, on the basis of the substrate information.

Preferably, the substrate transfer apparatus described above further includes a storage unit that stores a reference transfer operation of the hand, and
the control unit changes the transfer operation of the hand by changing an amount by which the hand is moved, the amount being an amount that defines the reference transfer operation of the hand.

[Operation and Effect] With the configuration described above, the substrate transfer apparatus stores therein the reference transfer operation of the hand. By editing the reference transfer operation of the hand, the transfer operation of the hand is changed to an appropriate one. With this configuration, the transfer operation of the hand can be changed easily and reliably.

In the substrate transfer apparatus described above, preferably, the substrate information includes a different piece of information for each of the substrates held in the carrier.

[Operation and Effect] With the configuration described above, the substrate information is different for each of the substrates held in the carrier, for example. With this configuration, even when different types of substrates are stored in one carrier, each of the substrates can be transferred reliably.

In the substrate transfer apparatus described above, preferably,
the substrate information includes information related to a substrate diameter,
the hand includes a guide member that comes into contact with a peripheral portion of the substrate, and
the control unit changes the transfer operation of the hand in such a manner that a position of the guide member is matched to a position of the peripheral portion of a substrate to be transferred.

[Operation and Effect] With the configuration described above, the substrate information includes information related to a substrate diameter, for example. The hand transfers the substrate using a transfer operation for matching the position of the guide member with the position of peripheral portion of the substrate to be transferred. With this configuration, even when substrates with different diameters are stored inside a single carrier, each of the substrates can be transferred reliably.

In the substrate transfer apparatus described above, preferably,
the substrate information includes information related to a substrate thickness, and
the control unit sets a position, in the vertical direction, at which the hand is advanced into the carrier, for each of the substrates, based on the substrate information.

[Operation and Effect] With the configuration described above, the substrate information includes, for example, information related to a substrate thickness. The position, in the vertical direction, at which the hand is advanced into to the carrier is set for each of the substrates, based on the substrate information. With this configuration, even when a thick substrate is held in the carrier, the hand does not damage the substrate by coming into contact with the substrate.

The substrate transfer apparatus described above preferably further includes a mapping unit that performs mapping of a substrate in the carrier,
the substrate information includes information related to a substrate thickness, and
the mapping unit sets a detection threshold on based on the substrate information.

[Operation and Effect] With the configuration described above, the substrate information includes, for example, information related to a substrate thickness. The mapping unit has a detection threshold appropriate for the thickness of the substrate. With the configuration described above, because the detection threshold is set on the basis of the substrate information, it is possible to performing the mapping of the substrates, on the basis of a detection threshold that is suitable for the mapping.

In the substrate transfer apparatus described above, preferably,
the substrate information includes information related to a substrate shape, and
the control unit sets a position, in the vertical direction, at which the hand is advanced into the carrier, for each of the substrates, based on the substrate information.

[Operation and Effect] With the configuration described above, the substrate information includes information related to a substrate shape, for example. The position, in the vertical direction, at which the hand is advanced into to the carrier is set for each of the substrates, based on the substrate information. With this configuration, even when substrates having different shapes are held in the carrier, the hand does not damage the substrate by coming into contact with the substrate.

In the substrate transfer apparatus described above, preferably, the information related to the substrate shape is an evaluation value indicating an amount of deformation of the substrate and a direction of the deformation of the substrate.

[Operation and Effect] With the configuration described above, the substrate information includes an evaluation value indicating the amount of deformation of the substrate and the direction of the deformation of the substrate. With this configuration, even when a warped substrate is held in the carrier, the hand does not damage the substrate by coming into contact with the substrate.

In the substrate transfer apparatus described above, preferably, the control unit sets an order in which the substrates inside the carrier are transferred, based on the substrate information.

[Operation and Effect] With the configuration described above, the substrate information includes information related to a substrate shape, for example. The order for transferring the substrates held in the carrier is set on the basis of the substrate information. As a result, it becomes possible to transfer the substrates that cannot be transferred in a particular order, reliably.

In the substrate transfer apparatus described above, preferably, the control unit sets a transfer speed of the hand based on the substrate information.

[Operation and Effect] With the configuration described above, the transfer speed of the hand is set on the basis of the substrate information. With this configuration, each of the substrates can be transferred at an appropriate transfer speed suitable for the substrate.

In the substrate transfer apparatus described above, preferably,
the substrate information includes information related to a pitch of the substrates stored inside the carrier, and
the control unit sets a position, in the vertical direction, at which the hand is advanced into the carrier, based on the substrate information.

[Operation and Effect] With the configuration described above, the substrate information includes information related to the pitch of the substrates stored inside the carrier. The position, in the vertical direction, at which the hand is advanced into the carrier is then set on the basis of the substrate information. With this configuration, because the transfer operation of the hand is changed on the basis of information other than the information related to the substrate itself, it is possible to transfer the substrate appropriately on the basis of a larger amount of information.

In the substrate transfer apparatus described above, preferably,
the receiving unit receives carrier information corresponding to the carrier, and
the control unit changes the transfer operation of the hand for each carrier, based on the carrier information received by the receiving unit.

[Operation and Effect] With the configuration described above, the substrate transfer apparatus receives the carrier information corresponding to a carrier. The transfer operation of the hand is then changed for each of the carriers, on the basis of the carrier information. With this configuration, the transfer operation of the hand can be changed for all of the substrates, in the unit of one carrier.

In the substrate transfer apparatus described above, preferably,
a plurality of protrusions capable of holding a substrate are arranged inside the carrier in the vertical direction,
the carrier information includes information related to a pitch of the protrusions, and
the control unit sets a position, in the vertical direction, at which the hand is advanced into the carrier, based on the carrier information.

[Operation and Effect] With the configuration described above, the carrier information includes information related to the pitch of the protrusions on the carrier. With this configuration, it is possible to set the position, in the vertical direction, at which the hand is advanced into the carrier on the basis of the pitch of the protrusions.

The substrate transfer apparatus described above, preferably, further includes a mapping unit that performs mapping of a substrate in the carrier, in which
the substrate information includes information related to a pitch of the substrates stored inside the carrier, and
the control unit causes the mapping unit to execute a mapping operation when at least the pitch of the protrusions, the pitch being a pitch in the carrier information, does not match the pitch of the substrates stored inside the carrier, the pitch being a pitch in the substrate information, and changes the transfer operation of the hand based on a result of the mapping operation.

[Operation and Effect] With the configuration described above, when the pitch of the protrusions does not match the pitch of the substrates stored inside the carrier, the former pitch being specified in in the carrier information and the latter pitch being specified in the substrate information, the mapping unit is caused to execute the mapping operation. As a result, the substrate distribution in the carrier is measured. With this configuration, even when there is an error in either the carrier information or the substrate information, the error is corrected before the substrate is transferred.

The substrate transfer apparatus described above preferably further includes a mapping unit that performs mapping of a substrate in the carrier, and
the control unit causes the mapping unit to execute a mapping operation at least when the pitch of the protrusions in the carrier information is equal to or larger than a predetermined value, and changes the transfer operation of the hand based on a result of the mapping operation.

[Operation and Effect] With the configuration described above, when the pitch of the protrusions in the carrier information is equal to or larger than the predetermined value, the mapping unit is caused to execute the mapping operation. As a result, the substrate distribution in the carrier is measured. With this configuration, even when there is an error in the carrier information, the error is corrected before the substrate is transferred.

The present invention disclosed herein also relates to a substrate processing apparatus that includes any of the substrate transfer apparatuses described above, and a substrate processing unit that performs predetermined processing on a substrate transferred by the substrate transfer apparatus.

[Operation and Effect] With the configuration described above, it is possible to provide a substrate processing apparatus capable of setting an appropriate substrate transfer method for each of the substrates, and of performing substrate processing.

The present invention disclosed herein also relates to a substrate processing system including a host computer that transmits, to the substrate processing apparatus, substrate information corresponding to each of the substrates held in the carrier.

[Operation and Effect] With the configuration described above, it is possible to provide a substrate processing system capable of setting an appropriate substrate transfer method for each of the substrates, and of performing substrate processing.

In addition to the aspects described above, the following aspects are disclosed herein.

In other words, the present invention provides a substrate transfer apparatus including:
a first hand that transfers one substrate at a time from a carrier that stores a plurality of substrates in horizontal postures with a large interval between the substrates in a vertical direction;
a second hand that transfers one substrate at a time from a carrier that stores a plurality of substrates in horizontal postures with a small interval between the substrates in the vertical direction; and
a control unit that control to advance and to retract the first hand or the second hand with respect to the substrate.

[Operation and Effect] The substrate transfer apparatus described above includes a control unit having two types of hands that are the first hand and the second hand, and transfers the substrate by using the first hand and the second hand, selectively. With such a configuration, it is possible to use the first hand to transfer substrates with a large interval between therebetween, and to use the second hand to transfer substrates with a small interval therebetween. In other words, with the substrate transfer apparatus according to the present invention, it is possible to transfer the substrates using a method more suitable for the actual conditions of the substrates stored in the carrier.

In the substrate transfer apparatus described above,
the first hand has a tip end provided with a first guide member that comes into contact with an end of a substrate;
the second hand has a tip end provided with a second guide member that comes into contact with an end of a substrate; and
the tip end of the second hand has a thickness thinner in a height direction than a thickness of the tip end of the first hand in the height direction.

[Operation and Effect] With the configuration described above, the tip end of the second hand has a thickness thinner in the height direction than the tip end of the first hand in the height direction. With this configuration, even when the distance between the substrates is small, it is possible to transfer the substrate to be transferred more reliably, by using the second hand.

In the substrate transfer apparatus described above,
the first hand includes a first holding body that extends in a first direction and holds one end of the substrate, and a second holding body that extends in the first direction and holds the other end of the substrate,
the second hand includes a first blade that extends in the first direction and holds one end of a substrate, and a second blade that extends in the first direction and holds the other end of the substrate, and
a space between the first holding body and the second holding body is smaller than a space between the first blade and the second blade.

[Operation and Effect] With the configuration described above, the space between the first holding body and the second holding body in the first hand is smaller than the space between the first blade and the second blade in the second hand. With such a configuration, the first hand can hold the substrate more reliably. By contrast,
the second hand can hold a warped substrate, reliably, between the first blade and the second blade.

In the substrate transfer apparatus described above,
the first hand includes a pusher that grips a substrate, and
the second hand does not include the pusher.

[Operation and Effect] With the configuration described above, the first hand includes the pusher that grips the substrate. With this, the first hand can hold the substrate reliably, and transfer the substrate at a high speed. The second hand does not have a pusher. With this configuration, it is possible to simplify the structure of the apparatus, and to reduce the thickness of the second hand in the height direction.

The substrate transfer apparatus according to the present invention can set an appropriate substrate transfer mode for each substrate.

### BRIEF DESCRIPTION OF THE DRAWINGS

FIG. 1 is a plan view for explaining the entire configuration of a substrate processing apparatus according to Embodiment 1;

FIG. 2 is a front view for explaining a configuration of a carrier according to Embodiment 1;

FIG. 3 is a front view for explaining the configuration of the carrier according to Embodiment 1;

FIG. 4 is a schematic diagram for explaining a configuration of a mapping device according to Embodiment 1;

FIG. 5 is a schematic diagram for explaining a configuration of an indexer robot according to Embodiment 1;

FIG. 6 is a plan view for explaining a pickup hand and a return hand according to Embodiment 1;

FIG. 7A is a schematic diagram for explaining a transfer operation of the pickup hand according to Embodiment 1;

FIG. 7B is a schematic diagram for explaining the transfer operation of the pickup hand according to Embodiment 1;

FIG. 7C is a schematic diagram for explaining the transfer operation of the pickup hand according to Embodiment 1;

FIG. 8A is a schematic diagram for explaining the transfer operation of the pickup hand according to Embodiment 1;

FIG. 8B is a schematic diagram for explaining the transfer operation of the pickup hand according to Embodiment 1;

FIG. 8C is a schematic diagram for explaining the transfer operation of the pickup hand according to Embodiment 1;

FIG. 9 is a front view for explaining the configuration of the carrier according to Embodiment 1;

FIG. 10 is a schematic diagram for explaining the transfer operation of the pickup hand according to Embodiment 1;

FIG. 11 is a flowchart for explaining an operation of the substrate processing apparatus according to Embodiment 1;

FIG. 12 is a plan view for explaining the operation of the substrate processing apparatus according to Embodiment 1;

FIG. 13 is a schematic diagram for explaining a configuration of an indexer robot according to Embodiment 2;

FIG. 14A is a schematic diagram for explaining a sensor holding member and a hand according to Embodiment 2;

FIG. 14B is a schematic diagram for explaining the sensor holding member and the hand according to Embodiment 2;

FIG. 15 is a plan view for explaining a first pickup hand and a first return hand according to Embodiment 2;

FIG. 16 is a plan view for explaining a second pickup hand and a second return hand according to Embodiment 2;

FIG. 17 is a flowchart for explaining an operation of a substrate processing apparatus according to Embodiment 2;

FIG. 18 is a schematic diagram for explaining a configuration according to one modification of the present invention; and

FIG. 19 is a schematic diagram for explaining the configuration according to the one modification of the present invention.

### DESCRIPTION OF THE PREFERRED EMBODIMENTS

Some embodiments of the present invention will now be described with reference to drawings. Each of the following embodiments is a substrate processing apparatus including a substrate transfer apparatus according to the present invention. The substrate transfer apparatus according to the present invention corresponds to an indexer block included in a substrate processing apparatus according to the embodiment. An indexer block includes an indexer robot having a hand for transferring a substrate.

### Embodiment 1

### 1. Overall Configuration

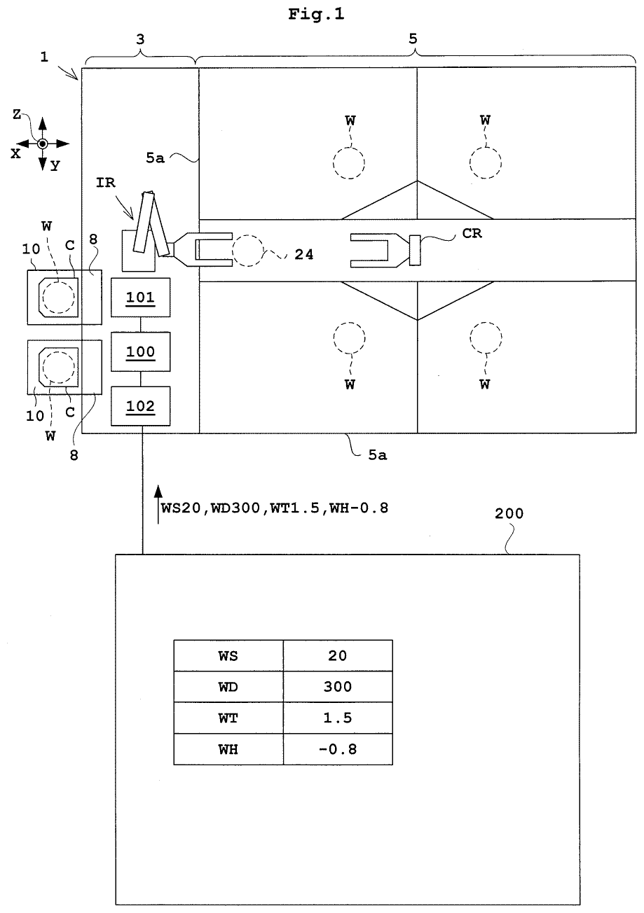

As illustrated in FIG. 1, a substrate processing apparatus 1 according to this example includes a load port 10, an indexer block 3, and a processing block 5. The substrate processing apparatus 1 according to this example is related to single-wafer processing, and is configured to pick up substrates W in horizontal postures one by one from a carrier C, perform substrate processing, and return the substrates W one by one into the carrier.

In the explanation herein, for the convenience of description, the direction along which the indexer block 3 and the processing block 5 are disposed in the substrate processing apparatus 1 will be referred to as a “front-back direction X”. The front-back direction X extends horizontally. In the front-back direction X, the direction from the processing block 5 toward the indexer block 3 in the substrate processing apparatus 1 will be referred to as “frontward”. The direction opposite to the frontward direction will be referred to as “rearward”. The direction extending horizontally and orthogonally to the front-back direction X will be referred to as “width direction Y”. One of the “width direction Y” will be referred to as “rightward” for the convenience of description, and the other will be referred to as “leftward” for the convenience of description. The direction orthogonal to the front-back direction X as well as to the width direction Y (height direction) will be referred to as a “vertical direction Z” for the convenience of description. In each of the drawings, the front side, the rear side, the right side, the left side, the upper side, and the lower side are indicated as appropriate, for reference.

The load port 10 is a carrier placement shelf for placing a carrier C. The plurality of load ports 10 are disposed along the width direction Y, and each of the plurality of load ports 10 is available for the placement of one carrier C.

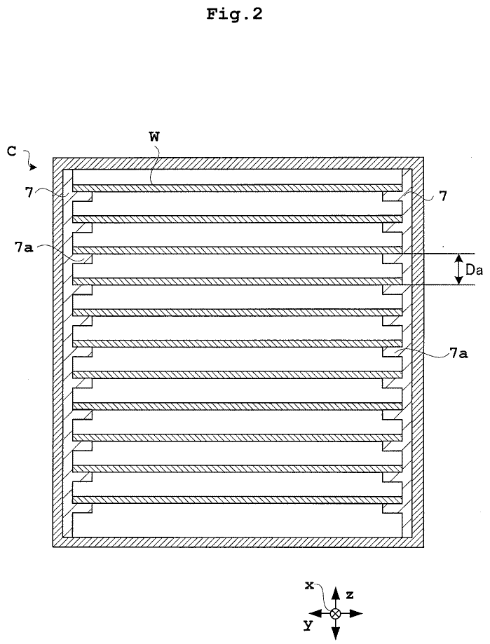

The carrier C stores therein a plurality of substrates W in horizontal postures, with a predetermined interval therebetween in the vertical direction Z. Within one carrier C, a plurality of (e.g., twenty five) substrates W in horizontal postures are stacked and stored at constant intervals. FIG. 2 is a cross-sectional view for explaining a configuration of the carrier C. In the carrier C, each end of the carrier housing has a comb-like member 7 having a plurality of protrusions 7a for placing the substrate W. The protrusions 7a of the comb-like member 7 are structures on which the ends of the substrate W are placed. The protrusion 7a extends in the front-back direction X. The protrusions 7a are provided at intervals of 10 mm. The pitch Da between the protrusions 7a is therefore 10 mm. One example of the carrier C is a sealed front opening unified pod (FOUP). In the present invention, it is also possible to use an open container as the carrier C.

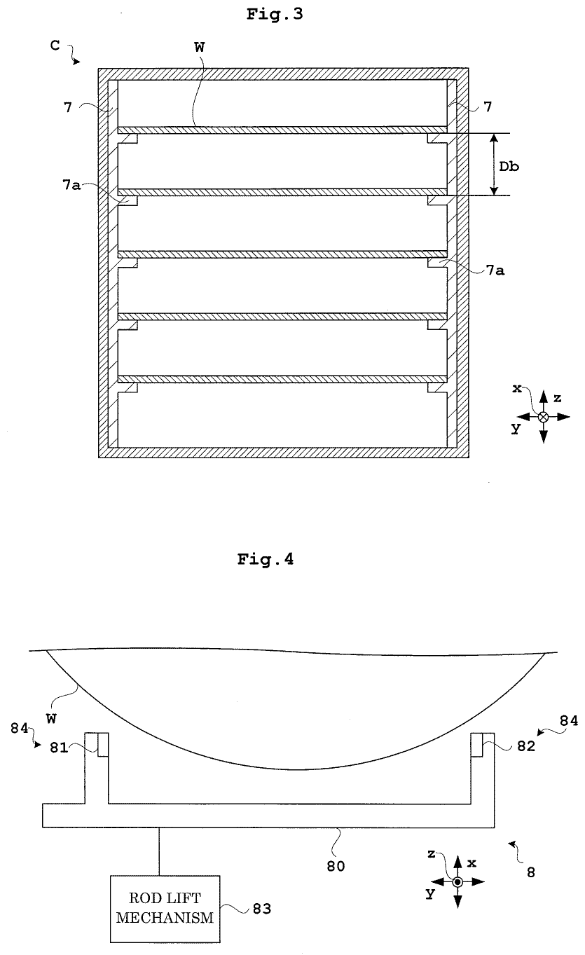

FIG. 3 illustrates another configuration of the carrier C. In the other example of the carrier C illustrated in FIG. 3, the pitch Db of the protrusions 7a is set to 20 mm. Such a carrier C can store a stack of thirteen substrates W, for example. The carrier illustrated in FIG. 3 is useful for housing heavy substrates W or extensively warped substrates W, for example.

The indexer block 3 corresponds to a substrate transfer apparatus according to the present invention. The indexer block 3 has a rectangular shape that is elongated in the width direction Y. The indexer block 3 includes a mapping device 8. As illustrated in FIG. 4, the mapping device 8 includes a rod 80 extending in the width direction Y. The rod 80 includes projections at a base end and a tip end, respectively. Each of the projections extends in the front-back direction X. Each of the projections has a mapping unit 84. In other words, one of the projections has a light emitter 81, and the other projection has a light receiver 82. The light emitter 81 and the light receiver 82 correspond to a mapping unit according to the present invention. The rod 80 is movable in the vertical direction Z. A rod lift mechanism 83 is a structure for raising and lowering the rod 80.

The mapping unit 84 performs mapping of the substrate W in the carrier C. The mapping unit 84 emits measurement light from the light emitter 81, and detects the presence of the substrate W by detecting the measurement light on the light receiver 82. The measurement light may be infrared light, for example. To detect the presence of a substrate W with the mapping unit 84, the light emitter 81 is positioned on the right side of the substrate, and the light receiver 82 is positioned on the left side of the substrate. If there is any substrate W between the light emitter 81 and the light receiver 82, the measurement light emitted from the light emitter 81 is blocked by the substrate W, and does not become incident on the light receiver 82, or the amount of the measurement light incident on the light receiver 82 becomes reduced. By making such measurement while moving the rod 80 in the vertical direction Z, it is possible to recognize in which parts of the carrier C have the substrates W. The mapping operation according to this example is performed in the manner described above. Before the substrates W are transferred from the carrier C, the rod 80 is moved to the bottom of the carrier C. Therefore, the rod 80 does not obstruct the indexer robot IR.

The indexer block 3 includes the indexer robot IR. The indexer robot IR has a hand capable of holding and transferring the substrate W. The indexer robot IR can access the carrier C on the load port 10, and a path 24 provided in front of the processing block 5. The indexer robot IR can perform two operations one of which is an operation of picking up the substrates W in the horizontal posture one by one from the carrier C and placing the substrate W on the path 24, and the other of which is an operation of picking up the substrates W in the horizontal posture one by one from the path 24, and returning the substrate W into the carrier C. The indexer robot IR transfers an unprocessed substrate W held in the carrier C onto the path 24. A processed substrate W is placed on the path 24, and is returned, by the indexer robot IR, to the carrier C.

The processing block 5 corresponds to a substrate processing unit according to the present invention. The processing block 5 is configured to perform predetermined processing on the substrate W having been transferred by the indexer block 3. The processing block 5 includes an arrangement of a plurality of single-wafer processing chambers 5a. In other words, three single-wafer processing chambers 5a are installed in each of a middle layer region, an upper layer region, and a lower layer region, to form a stack. Two stacks are disposed in the front side and the rear side, respectively, on the right side of the processing block 5. In the same manner, two stacks are disposed on the front side and the rear side, respectively, on the left side of the processing block 5. Therefore, twelve single-wafer processing chambers 5a in total are installed in the processing block 5. Along the center of the processing block 5, a substrate transfer section extending in the front-back direction X is provided. A center robot CR is enabled to move back and forth along the substrate transfer section, and to pick up one substrate W, in the horizontal posture, at a time from the path 24, and transfer the substrate W into one of the single-wafer processing chambers 5a. The center robot CR is also enabled to pick up one substrate W, in the horizontal posture, at a time from the single-wafer processing chamber 5a, and to return the substrate W to the path 24. In the manner described above, the center robot CR is enabled to access each of the single-wafer processing chambers 5a and the path 24.

An example of the substrate processing performed in the single-wafer processing chamber 5a includes substrate cleaning processing. The substrate processing apparatus 1 according to this example may be configured to perform various types of substrate processing that uses a chemical liquid, in addition to the substrate cleaning processing.

### 2. Configuration of Indexer Robot

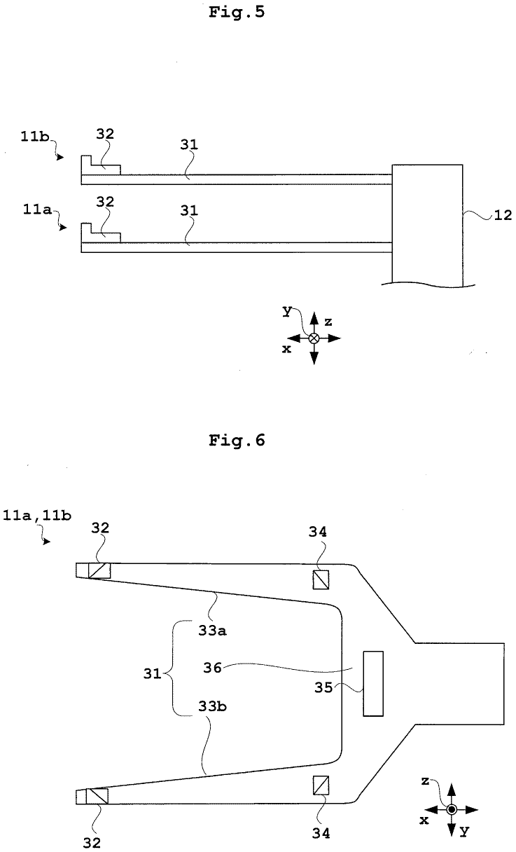

FIG. 5 schematically illustrates tip ends of the indexer robot IR, the tip ends being involved in holding of a substrate. The indexer robot IR includes a pickup hand 11a and a return hand 11b. The return hand 11b and the pickup hand 11a are disposed on top of each other in the vertical direction Z, and held by an arm 12. The arm 12 can cause the return hand 11b and the pickup hand 11a to advance and to retreat independently, in the front-back direction X. The pickup hand 11a and the return hand 11b are held at the same position in the front-back direction X before being inserted between the substrates W. In the configuration illustrated in FIG. 5, the return hand 11b and the pickup hand 11a are arranged from the top to the bottom, in the order listed herein, but the order in which these members are arranged may be changed as appropriate.

The pickup hand 11a corresponds to a hand according to the present invention. The pickup hand 11a holds one unprocessed substrate W at a time from the carrier C, and transfers the substrate W onto the path 24. The pickup hand 11a has a hand body 31. The hand body 31 has a flat shape so as to be able to advance into the space between the substrates. The pickup hand 11a includes a guide member 32 that comes into contact with a peripheral portion of the substrate W. The guide member 32 is positioned at the tip end of the pickup hand 11a, and is configured to abut against the end of the substrate W. In other words, the guide member 32 is a tab provided at the tip end of the hand body 31, and is a member that comes into contact with the substrate W. The guide member 32 is provided on the top surface of the hand body 31. The guide member 32 is thus configured to hold the upper substrate W from the bottom. The guide member 32 has a thick portion and a thin portion. The guide member 32 thus has parts with different thicknesses in the height direction. A wall provided to the thick portion of the guide member 32, the wall facing the base end of the pickup hand 11a, can come into contact with the peripheral end (bevel portion) of the substrate W. A flat part of the thin portion of the guide member 32, the flat part facing upwards, can come into contact with the peripheral portion of the bottom surface of the substrate. A guide member is also provided at the base end of the hand body 31 (not illustrated in FIG. 3). These guide members form a contact portion that comes into contact with the substrate W, in the pickup hand 11a.

The return hand 11b has the same configuration as the pickup hand 11a described above. In other words, the return hand 11b includes the hand body 31 and the guide member 32. The return hand 11b and the pickup hand 11a share the same configuration in which the guide members 32 are provided at the tip end and the base end of the hand body 31, respectively, and each of the guide member 32 has a thick portion and a thin portion. The return hand 11b according to this example is provided to transfer cleaned substrates W. By using different hands in a path for moving forwards and a path for moving rearwards in the operation of moving the substrate W back and forth, it is not necessary to use a hand having held an uncleaned substrate W in holding a cleaned substrate W. Therefore, by providing the return hand 11b, the cleanliness of the cleaned substrate W can be maintained.

FIG. 6 is a plan view for explaining the pickup hand 11a and the return hand 11b. Each of the pickup hand 11a and the return hand 11b includes a base end 36, and a first holding body 33a and a second holding body 33b that are branched out from the base end 36. The first holding body 33a is a member extending in the front-back direction X and holding one end of the substrate W, and the second holding body 33b is a member extending in the front-back direction X and holding the other end of the substrate W. The guide members 32 are provided at the tip ends of the first holding body 33a and of the second holding body 33b, respectively.

Guide members 34 are provided on the base ends of the first holding body 33a and of the second holding body 33b, respectively. In the same manner as the guide members 32 described above, each of the guide members 34 includes a thick portion having a wall with which the end (bevel portion) of the substrate W can come into contact, and a thin portion having a flat portion with which the peripheral portion of the bottom of the substrate can come into contact. The thick portion of the guide member 34 has the same thickness as the thick portion of the guide member 32. The thin portion of the guide member 34 has the same thickness as the thin portion of the guide member 32. The walls of the guide members 32 and the guide members 34 are provided at positions belonging to a virtual circle that is slightly larger than the substrate W. As a result, the substrate W can fit inside the area for receiving the substrate W, the area being delineated by the thin portions of the guide members 32 and of the guide members 34.

A pusher 35 is provided to the tip end of the base end 36, and can push the substrate W held by the guide members 32 and the guide members 34 in the frontward direction. The pusher 35 is enabled to open by moving rearwards, and to close by moving in the frontward direction. In order for the first holding body 33a and the second holding body 33b to hold the substrate W, to begin with, the guide members 32 and the guide members 34 are caused to hold the substrate W, with the pusher 35 opened. The pusher 35 is then closed, so as to nip the substrate W between the guide members 32 and the pusher 35. The substrate W is gripped in the manner described above.

### 3. Basic Operation of Indexer Robot

An operation of the indexer robot IR will now be described. For the indexer robot IR, reference transfer operations of the pickup hand 11a and the return hand 11b are defined. The indexer robot IR can change the amount by which the hand is moved, the amount defining the reference transfer operation of the hand, to change the transfer operation of the hand. In other words, the indexer robot IR transfers various substrates W suitably, by making fine adjustments of the basic operation.

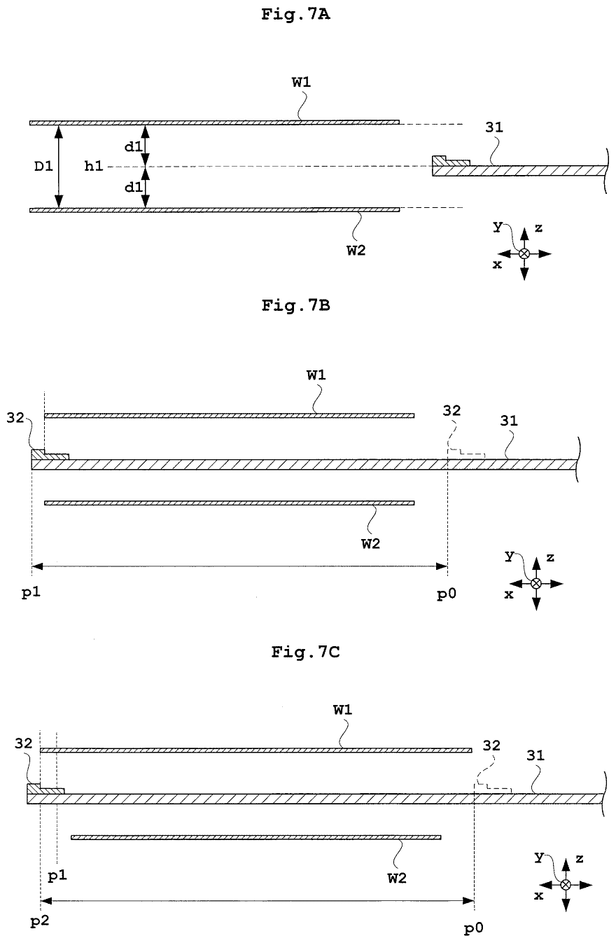

To begin with, the reference operation of the indexer robot IR will be described. FIG. 7A illustrates the position of the pickup hand 11a having raised to a level near the first substrate W1 when the first substrate W1 that is a substrate to be transferred is to transferred. In other words, the indexer robot IR moves the arm 12 in the vertical direction Z and brings the pickup hand 11a to the height at the midpoint between the first substrate W1 being the substrate to be transferred and the substrate W2 disposed below the first substrate W1. The first substrate W1 and the second substrate W2 in FIG. 7A are flat without any warpage. Therefore, the distance between the substrates is constant regardless of the positions in the front-back direction X. The distance D1 is the ideal distance between substrates defined by the comb-like member 7 of the carrier C. Specifically, the distance D1 is a length obtained by subtracting the thickness of the substrate W defined in its standard, from the distance between the protrusions 7a of the comb-like member 7. The distance between the protrusions 7a of the comb-like member 7 is equal to the distance between the bottom surface of the first substrate W1 and the bottom surface of the second substrate W2. However, required in transferring the first substrate W1 using the pickup hand 11a is the distance between the bottom surface of the first substrate W1 and the top surface of the second substrate W2. This distance between the substrates therefore is shorter than the distance between the protrusions 7a of the comb-like member 7 by the thickness of the second substrate W2. The position of the pickup hand 11a in FIG. 7A is set higher than the second substrate W2 by a distance d1 that is a half the distance D1. The pickup hand 11a therefore is at the position lower than the first substrate W1 by the distance d1. In this manner, the pickup hand 11a is passed through just in the middle between the first substrate W1 and the second substrate W2. Therefore, it is possible to reduce the chances of the pickup hand 11a colliding with the first substrate W1 or with the second substrate W2.

FIG. 7A illustrates the reference transfer operation of the pickup hand 11a. The distance between the substrates is D1. The arm 12 moves the pickup hand 11a in the vertical direction Z in such a manner that the distance between the bottom surface of the pickup hand 11a and the top surface of the second substrate W2 becomes equal to the distance between the top surface of the thick portion of the guide member 32 on the pickup hand 11a and the bottom surface of the first substrate W1. When the distance between the substrates is D1, as indicated in FIG. 7A, a reference position of the pickup hand 11a is set to the position higher than the second substrate W2 by d1. That is, the reference position of the pickup hand 11a is matched to the position (reference height h1) higher than the surface (top surface) of the second substrate W2 by d1. d1 is a half the distance D1. The reference position of the pickup hand 11a in the vertical direction Z is set to the position at the middle of the pickup hand 11a having a predetermined thickness. The length of the thick portion of the guide member 32 between the reference position and the top end is equal to the length between the reference position and the bottom end of the hand body 31. Therefore, the reference position corresponds to the midpoint between the top end of the thick portion of the guide member 32 and the bottom end of the hand body 31.

The pickup hand 11a is then moved forwards, as illustrated in FIG. 7B. The pickup hand 11a is stopped at the point where the thick portion of the guide member 32 comes outside of the first substrate W1 in the front-back direction X. During this process, the tip end of the pickup hand 11a moves from a position p0 to a position p1. As a result, the walls of the guide members 32 and the guide members 34 come to the positions belonging to a virtual circle that is slightly larger than the substrate W.

The pickup hand 11a is then moved up. The top end of the thin portion of the guide member 32 then abuts against the peripheral portion of the first substrate W1. When the pickup hand 11a is raised further, the first substrate W1 separates from the protrusions 7a of the comb-like member 7, and is lifted by supported on the pickup hand 11a. In this condition, the pusher 35 closes, and causes the pickup hand 11a to grip the first substrate W1. By then moving the pickup hand 11a rearwards, the first substrate W1 being the substrate to be transferred is transferred out of the carrier C.

The basic operation of the pickup hand 11a has been explained above. There is also a reference transfer operation for the return hand 11b. The basic operation of the return hand 11b can be achieved by temporally reversing the basic operation of the pickup hand 11a. The return hand 11b gripping the substrate W is moved forwards, and the pusher 35 is opened. At this time, the substrate W having been gripped by the return hand 11b is released. Once the return hand 11b is lowered, the substrate W rests on the protrusions 7a of the comb-like member 7, and separates from the return hand 11b. When the reference position reaches the reference height h1, the return hand 11b is stopped. From this point, the return hand 11b is moved rearwards, and retracted from the carrier C. The reference position of the return hand 11b is the same as the reference position of the pickup hand 11a. In other words, the reference position corresponds to the midpoint between the top end of the thick portion of the guide member 32 and the bottom end of the hand body 31.

### 4. Substrate Information

The substrate transfer apparatus according to this example is characterized in that the operations of the pickup hand 11a and the return hand 11b are finely adjusted on the basis of the substrate information. In other words, the substrate transfer apparatus according to this example changes the transfer operations of the pickup hand 11a and the return hand 11b for each substrate, on the basis of the substrate information. Specifically, the transfer operations of the pickup hand 11a and the return hand 11b are changed by changing the amounts by which the pickup hand 11a and the return hand 11b are moved, specified in the reference transfer operation of the pickup hand 11a and the return hand 11b described above. Before describing this configuration, substrate information according to this example will be described. The substrate information is information unique to each substrate stored in the carrier C, and may be different among the substrates held in the carrier C.

The substrate information according to this example includes, for example, information related to the pitch of the substrates W stored in the carrier C. A carrier C having the protrusions 7a at a pitch of 10 mm is capable of storing twenty five substrates W at the maximum. However, in order to ensure some extra space inside the carrier C, the substrates W may be disposed at a pitch of 20 mm in the carrier C, for example. The substrate information according to this example includes information indicating whether a substrate W is stored in every space that is available as a storage of a substrate W in the carrier C. By reading the substrate information, the pitch of the substrates W stored in the carrier C can be obtained.

The substrate information also includes information related to a substrate diameter, for example. The carrier C can store substrates W having different diameters. There are some substrates W having a diameter of 300 mm, and there are some others having a diameter of 301 mm. All of these plurality of types of substrates W can be stored in the same carrier C. The substrate information according to this example includes information related to the substrate diameter of each of the substrates W stored in the carrier C. By reading the substrate information, it is possible to recognize the position where a substrate W having a diameter of 300 mm is stored in the carrier C. In the same manner, by reading the substrate information, it is possible to recognize the position where a substrate W having a diameter of 301 mm is stored in the carrier C.

The substrate information also includes information related to the thickness of the substrate, for example. The carrier C can also store substrates W having different thicknesses. The substrate W includes those with the same thickness as that resultant of cutting from the single crystal ingot, and those with a thickness twice that thickness, with two substrates being bonded to each other, for example. All of these plurality of types of substrates W can be stored in the same carrier C. The substrate information according to this example includes information related to the substrate thickness of each of the substrates W stored in the carrier C. By reading the substrate information, it is possible to recognize the position where a substrate W having which thickness is stored in the carrier C.

The substrate information also includes information related to a substrate shape, for example. The carrier C can also store substrates W having different shapes. There are some substrates W that are flat, and some others having an upward bulge at the center (umbrella-shaped substrate) or a downward recess at the center (bowl-shaped substrate). All of these plurality of types of substrates W can be stored in the same carrier C. The substrate information according to this example includes an evaluation value indicating the amount and the direction of the distortion of the substrate, for each of the substrates W stored in the carrier C. An evaluation value of zero indicates that the substrate is flat, and a positive evaluation value indicates the substrate is an umbrella-shaped substrate. A negative evaluation value indicates that the substrate is a bowl-shaped substrate. By reading the substrate information, it is possible to recognize at which position a substrate W distorted in which direction by what degree is stored inside the carrier C.

An actual format of the substrate information is a character string, for example. The substrate information is merged and handled as a set of character string information, in units of one carrier C. The character string information includes a value appended with “WS”. The value appended with “WS” represents the pitch of the substrates W stored in the carrier C. The character string information includes a value appended with “WD”. The value appended with “WD” represents the diameter of the substrate W in the carrier C. The character string information includes a value appended with “WT”. The value appended with “WT” represents the thickness of the substrate W in the carrier C. The character string information includes a value appended with “WH”. The value appended with “WH” represents the shape of the substrate W in the carrier C. The substrate information related to “WS” is a value determined by carrier C. The substrate information related to “WD”, “WT”, and “WH” are values that are unique to each substrate W. Therefore, specifically, for “WD”, for example, twenty five variables, e.g., “WDa”, “WDb”, . . . , “WDx”, and “WDy” are prepared for the respective twenty five substrates W in the carrier C. The same applies to “WT” and “WH”. When “WDa” to “WDy” take the same value within the carrier C, only “WD” may be used to identify the diameter of such substrates. The same applies to “WT” and “WH”. Character string information “WS20, WD300, WT1.5, WH-0.8” corresponding to a carrier C indicates that the substrates W are disposed at a pitch of 20 mm in the carrier C; each of the substrates W has a diameter of 300 mm; each of the substrates W has a thickness of 1.5 mm; and each of the substrates W has a bowl-like shape recessed at the center by 0.8 mm. In this example, all of the substrates W stored in the carrier C have the same diameter, the same thickness, and the same shape.

### 5. Fine Adjustments of Transfer Operation

Described now is how the transfer operations of the pickup hand 11a and the return hand 11b are finely adjusted on the basis of the substrate information. The reference transfer operation is set for the pickup hand 11a, as described above. This transfer operation is an operation suitable for transferring a thin and flat substrate W having a diameter of 300 mm. When any substrate W to be transferred is found to deviate from any of these conditions, as a result of reading the substrate information, the indexer robot IR makes a fine adjustment of the transfer operation. As a result of the fine adjustment, a transfer operation suitable for transferring the substrate W to be transferred is achieved. In the fine adjustment of the transfer operation, the indexer robot IR also refers to the substrate information related to the substrate W positioned below the substrate W to be transferred.

FIG. 7C illustrates how the fine adjustment of the transfer operation is carried out when the substrate W to be transferred has a diameter larger than 300 mm. When a first substrate W1 with a larger diameter is to be transferred, the distance by which the pickup hand 11a is moved forwards is extended, with respect to that in the reference transfer operation. The tip end of the pickup hand 11a is therefore moved from the position p0 to a position p2. As can be seen with reference to FIG. 7C, the position p2 is farther away from the position p0 (the initial position of the pickup hand 11a) than the position p1. Therefore, when the first substrate W1 having a larger diameter is to be transferred, the tip of the pickup hand 11a, which has been originally at the position p0, passes through the position p1, and stops at the position p2. As a result, the walls of the guide members 32 and the guide members 34 come to the positions belonging to a virtual circle that is slightly larger than the first substrate W1. The first substrate W1 being the substrate to be transferred has a larger diameter, and therefore, the rim (bevel portion) of the first substrate W1 extends frontwards further than that assumed in the reference operation of the pickup hand 11a. Therefore, unless the fine adjustment of the transfer operation is made, the thick portion of the guide member 32 may collide with the rim (bevel portion) of the first substrate W1. In this example, for the purpose of avoiding such a situation, the amount by which the pickup hand 11a is moved forwards is extended with respect to the reference amount. As a result, because the thick portion of the guide member 32 sticks out further toward the front than the first substrate W1, which is the substrate to be transferred, the thick portion of the guide member 32 does not collide with the rim (bevel portion) of the first substrate W1, even when the pickup hand 11a is raised. The peripheral portion of the first substrate W1 rests on the thin portion of the guide member 32, and therefore, the first substrate W1 can be transferred in the same manner as the substrate W having a normal diameter. In this manner, the transfer operation of the pickup hand 11a is changed in such a manner that the guide member 32 comes to the position of the peripheral portion of the substrate to be transferred.

The operation of the pickup hand 11a has been described above. The fine adjustment of the operation of the return hand 11b is carried out in the same manner. The operation of the return hand 11b is an operation that is temporal reversal of the pickup hand 11a. The return hand 11b gripping the substrate W is moved forwards. The tip of the return hand 11b stops at the position p2. The subsequent operation is the same as the operation of the return hand 11b described above.

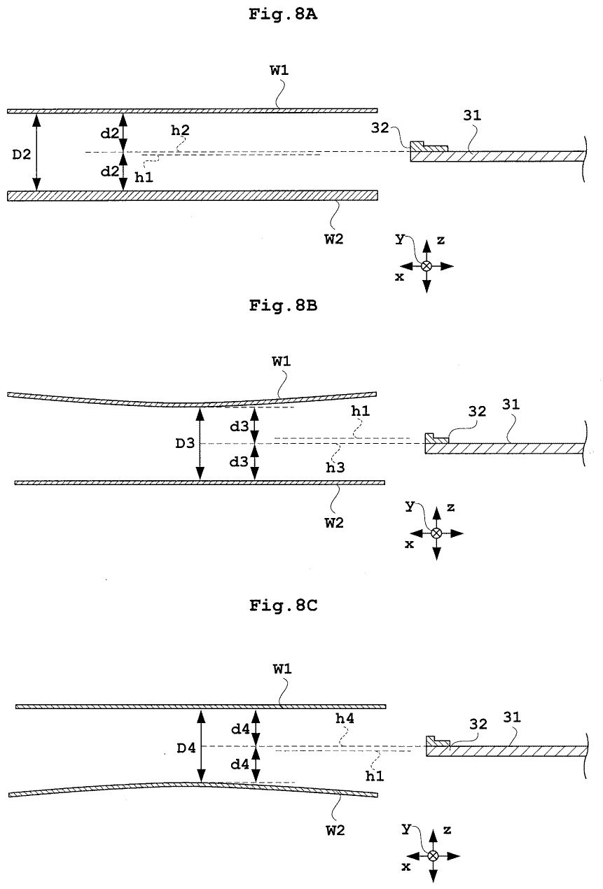

FIG. 8A illustrates how the fine adjustment of the transfer operation is carried out when the second substrate W2 positioned below the first substrate W1 being the substrate to be transferred is a thick substrate. When the first substrate W1 positioned above the thick second substrate W2 is to be transferred, the distance between these substrates is D2. The distance D2 is shorter than the distance D1 described above. This is because the second substrate W2 is thicker than that in the example illustrated in FIG. 7A. The arm 12 moves the pickup hand 11a in the vertical direction Z in such a manner that the distance between the bottom surface of the pickup hand 11a and the top surface of the second substrate W2 becomes equal to the distance between the top surface of the thick portion of the guide member 32 on the pickup hand 11a and the bottom surface of the first substrate W1. In other words, the pickup hand 11a is stopped at a position h2 higher than the reference height h1. When the distance between the substrates is D2, as illustrated in FIG. 8A, the reference position of the pickup hand 11a is set higher than the second substrate W2 by d2. Therefore, the reference position of the pickup hand 11a is matched to the position (position h2) higher than the surface (top surface) of the second substrate W2 by d2. d2 is a half the distance D2. In this manner, the pickup hand 11a is passed through just in the middle between the first substrate W1 and the second substrate W2. Therefore, it is possible to reduce the chances of the pickup hand 11a colliding with the first substrate W1 or with the second substrate W2. As described above, the position, in the vertical direction Z, at which the pickup hand 11a is advanced into the carrier C is set for each of the substrate W, on the basis of the substrate information.

The operation of the pickup hand 11a has been described above. The fine adjustment of the operation of the return hand 11b is carried out in the same manner. The operation of the return hand 11b is an operation that is temporal reversal of the pickup hand 11a. The return hand 11b having placed the substrate W on the protrusion 7a is lowered and stopped. At this time, the reference position of the return hand 11b is matched to h2, instead of the reference height h1. The subsequent operation is the same as the operation of the return hand 11b described above.

FIG. 8B illustrates how the fine adjustment of the transfer operation is carried out when the first substrate W1 being the substrate to be transferred is a warped substrate. When the bowl-shaped first substrate W1 is to be transferred, the shortest distance between the substrates is D3. The distance D3 is shorter than the distance D1 described above. This is because the first substrate W1 is recessed with respect to the second substrate W2, as compared with the example illustrated in FIG. 7A. The arm 12 moves the pickup hand 11a in the vertical direction Z in such a manner that the distance between the bottom surface of the pickup hand 11a and the top surface of the second substrate W2 becomes equal to the distance between the top surface of the thick portion of the guide member 32 on the pickup hand 11a and the bottom surface of the first substrate W1. In other words, the pickup hand 11a is stopped at a position h3 lower than the reference height h1. When the distance between the substrates is D3 as illustrated in FIG. 8B, the reference position of the pickup hand 11a is set higher than the second substrate W2 by d3. Therefore, the reference position of the pickup hand 11a is matched to the position h3 that is higher than the surface (top surface) of the second substrate W2 by d3. d3 is a half the distance D3. In this manner, the pickup hand 11a is passed through just in the middle between the first substrate W1 and the second substrate W2. Therefore, it is possible to reduce the chances of the pickup hand 11a colliding with the first substrate W1 or with the second substrate W2. As described above, the position, in the vertical direction Z, at which the pickup hand 11a is advanced into the carrier C is set for each of the substrate W, on the basis of the substrate information.

The operation of the pickup hand 11a has been described above. The fine adjustment of the operation of the return hand 11b is carried out in the same manner. The operation of the return hand 11b is an operation that is temporal reversal of the pickup hand 11a. The return hand 11b having placed the substrate W on the protrusion 7a is lowered and stopped. At this time, the reference position of the return hand 11b is matched to h3, instead of the reference height h1. The subsequent operation is the same as the operation of the return hand 11b described above.

FIG. 8C illustrates how the fine adjustment of the transfer operation is carried out when the second substrate W2 positioned below the first substrate W1 being the substrate to be transferred is a warped substrate. When an umbrella-shaped second substrate W2 is positioned below the first substrate W1 being the substrate to be transferred, the shortest distance between the substrates is D4. The distance D4 is shorter than the distance D1 described above. This is because the second substrate W2 is bulged with respect to the first substrate W1, as compared with the example illustrated in FIG. 7A. The arm 12 moves the pickup hand 11a in the vertical direction Z in such a manner that the distance between the bottom surface of the pickup hand 11a and the top surface of the second substrate W2 becomes equal to the distance between the top surface of the thick portion of the guide member 32 on the pickup hand 11a and the bottom surface of the first substrate W1. In other words, the pickup hand 11a is stopped at a position h4 higher than the reference height h1. When the distance between the substrates is D4 as illustrated in FIG. 8B, the reference position of the pickup hand 11a is set higher than the second substrate W2 by d4. Therefore, the reference position of the pickup hand 11a is matched to the position h4 that is higher than the surface (top surface) of the second substrate W2 by d4. d4 is a half the distance D4. In this manner, the pickup hand 11a is passed through just in the middle between the first substrate W1 and the second substrate W2. Therefore, it is possible to reduce the chances of the pickup hand 11a colliding with the first substrate W1 or with the second substrate W2. As described above, the position, in the vertical direction Z, at which the pickup hand 11a is advanced into the carrier C is set for each of the substrate W, on the basis of the substrate information.

The operation of the pickup hand 11a has been described above. The fine adjustment of the operation of the return hand 11b is carried out in the same manner. The operation of the return hand 11b is an operation that is temporal reversal of the pickup hand 11a. The return hand 11b having placed the substrate W on the protrusion 7a is lowered and stopped. At this time, the reference position of the return hand 11b is matched to h4, instead of the reference height h1. The subsequent operation is the same as the operation of the return hand 11b described above.

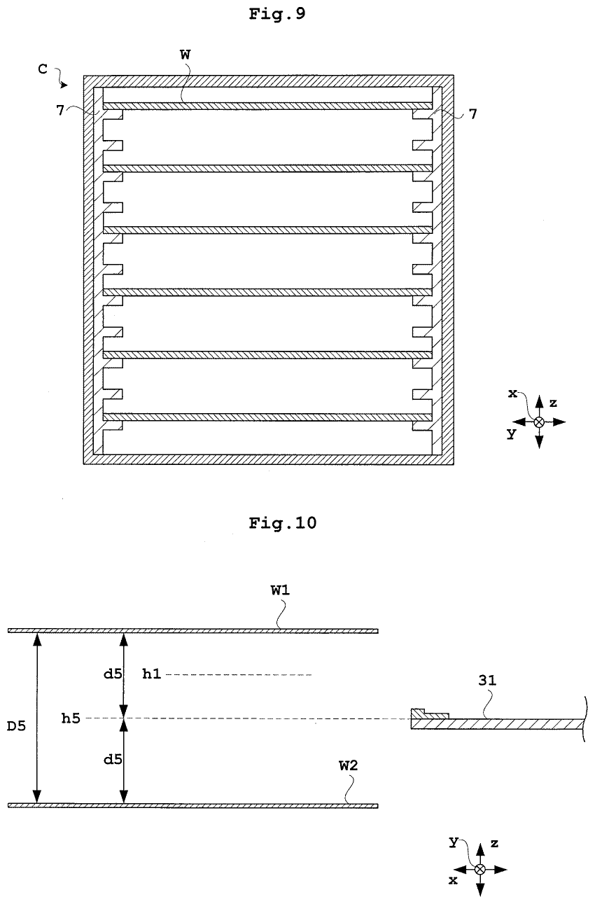

Use of the pitch of the substrates W specified in the substrate information will now be described. The pitch of the substrates W is indicated by a symbol “WS” in the substrate information. In other words the symbol “WS10” in the substrate information means that the substrates W are disposed in the carrier C at a pitch of 10 mm, as illustrated in FIG. 2. The symbol “WS20” in the substrate information means that the substrates W are disposed in the carrier C at a pitch of 20 mm, as illustrated in FIG. 9.

FIG. 10 illustrates how the fine adjustment of the transfer operation is carried out when the pitch between the first substrate W1 and the second substrate W2 is 20 mm. In such a setting, the distance between the substrates is D5. The distance D5 is longer than the distance D1 described above. The arm 12 moves the pickup hand 11a in the vertical direction Z in such a manner that the distance between the bottom surface of the pickup hand 11a and the top surface of the second substrate W2 becomes equal to the distance between the top surface of the thick portion of the guide member 32 on the pickup hand 11a and the bottom surface of the first substrate W1. In other words, the pickup hand 11a stops at a position h5 that is lower than the reference height h1. When the distance between the substrates is D5 as illustrated in FIG. 10, the reference position of the pickup hand 11a is set higher than the second substrate W2 by d5. Therefore, the reference position of the pickup hand 11a is matched to the position h5 that is higher than the surface (top surface) of the second substrate W2 by d5. d5 is a half the distance D5. In this manner, the pickup hand 11a is passed through just in the middle between the first substrate W1 and the second substrate W2. Therefore, it is possible to reduce the chances of the pickup hand 11a colliding with the first substrate W1 or with the second substrate W2.

The operation of the pickup hand 11a has been described above. The fine adjustment of the operation of the return hand 11b is carried out in the same manner. The operation of the return hand 11b is an operation that is temporal reversal of the pickup hand 11a. The return hand 11b having placed the substrate W on the protrusion 7a is lowered and stopped. At this time, the reference position of the return hand 11b is matched to h5, instead of the reference height h1. The subsequent operation is the same as the operation of the return hand 11b described above.

### 6. Other Configurations

As can be seen with reference to FIG. 1, the substrate transfer apparatus according to this example includes a control unit 100. The control unit 100 is implemented as a central processing unit (CPU), for example. As a specific configuration of the control unit 100, the control unit 100 may be implemented as a single processor, or individual processors, for example, but without limitation thereto.

Examples of control related to the control unit 100 include control related to the indexer robot IR. In other words, the control unit 100 controls the operations of the pickup hand 11a and the return hand 11b in the front-back direction, the operation of opening and closing the pusher 35, the movements of the arm 12 in the vertical direction Z, the mapping device 8, and the mapping unit 84. In particular, the control unit 100 changes the transfer operation of the pickup hand 11a for each of substrates, on the basis of the substrate information. Specifically, the control unit 100 changes the amount by which the pickup hand 11a is moved, in the reference transfer operation of the pickup hand 11a.

A storage unit 101 is a storage device accessed when the control unit 100 operates. The storage unit 101 stores therein programs and parameters related to control, character string information serving as the substrate information, and the like. In particular, the storage unit 101 stores therein the reference transfer operation of the pickup hand 11a. The storage unit 101 may be configured on a single device, or may be configured on individual devices corresponding to the respective control units. Furthermore, the substrate transfer apparatus according to this example has no particular limitation as to the configuration of the device for implementing the storage unit 101.

An input/output device 102 corresponds to a receiving unit according to the present invention. The input/output device 102 can be accessed when the control unit 100 operates. The input/output device 102 is connected to a host computer 200 of a plant, on the basis of a predetermined protocol. The host computer 200 transmits the substrate information corresponding to each of the substrates W held in the carrier C, to the substrate processing apparatus 1. The input/output device 102 can acquire the substrate information and carrier information, which will be described later, from the host computer 200. The input/output device 102 receives the substrate information corresponding to each of the substrates held in the carrier C. The substrate processing apparatus 1 and the host computer 200 together make up the substrate processing system according to the present invention.

### 7. Sequence of Substrate Transfer

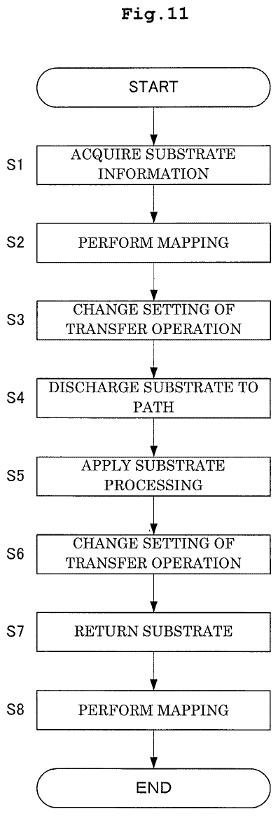

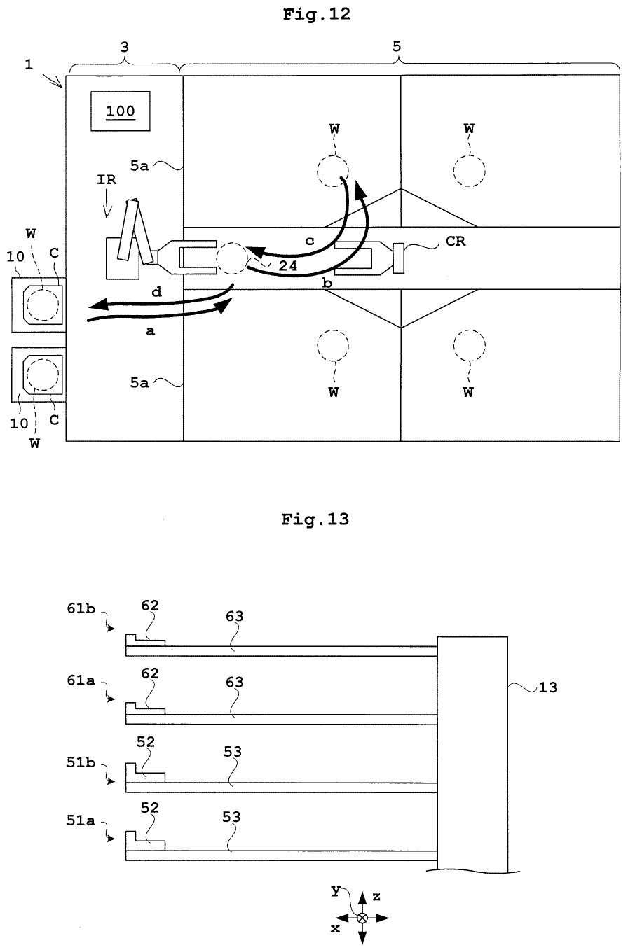

FIG. 11 is a flowchart of an operation for explaining the substrate transfer apparatus according to the present invention. An operation of the substrate transfer apparatus performed when the substrate processing apparatus 1 according to the present invention performs a substrate cleaning process will now be described. FIG. 12 illustrates how the substrate W is transferred inside the substrate processing apparatus 1. In the following description, FIG. 12 is also referred to, as appropriate.

Step S1: When a carrier C to be processed is placed at the load port 10, the substrate transfer apparatus acquires the substrate information of the substrates W stored in the carrier C, from the host computer 200. In the host computer 200, a plurality of pieces of substrate information are organized for respective carriers C. The input/output device 102 accesses the host computer 200, and acquires character string information corresponding to the carrier C placed at the load port 10. As described above, the character string information is configured as the substrate information merged for each of the carriers C. The character string information can be created by making actual measurements of the substrates in the carrier C, using a three-dimensional measuring instrument, before the carrier C is placed on the load port 10. The character string information may also be created manually by a user. The host computer 200 stores therein the character string information corresponding to a plurality of carriers C. In order to map the character string information stored in the host computer 200 to the carrier C placed on the load port 10, it is possible to refer to a tag (such as a barcode) that is unique to the carrier C.

Step S2: The substrate transfer apparatus starts a mapping operation of the substrates W. Specifically, the mapping operation is performed by moving the mapping unit 84 in the vertical direction Z with respect to the carrier C. As a result, it is possible to recognize which parts of the comb-like member 7 of the carrier C the substrates W are placed. The mapping operation is an operation for acquiring the distribution of the substrates W in the carrier C.

Step S3: The height of the reference position of the pickup hand 11a and the depth into which the pickup hand 11a is advanced into the carrier C are determined on the basis of the substrate information. Parameters related to the control of the pickup hand 11a are changed in such a manner that the pickup hand 11a performs the determined operation. Specifically, this step is implemented as a fine adjustment of the reference transfer operation of the pickup hand 11a.

Step S4: The arm 12 of the indexer robot IR is moved in the vertical direction, and positions the pickup hand 11a at the height of the substrate W to be transferred. The height of the pickup hand 11a at this time is a height suitable for transferring the substrate W to be transferred. The arm 12 of the indexer robot IR moves the pickup hand 11a forwards so that the pickup hand 11a is advanced into the carrier C. The amount by which the pickup hand 11a is moved at this time is set in a manner suitable for the diameter of the substrate to be transferred. The pickup hand 11a grips the substrate W to be transferred, and discharges the substrate W onto the path 24 (see the arrow a in FIG. 12).

Step S5: The unprocessed substrate W held on the path 24 is transferred to the single-wafer processing chamber 5a by the center robot CR (see an arrow b in FIG. 12). The single-wafer processing chamber 5a performs cleaning processing on the substrate W. The processed substrate W is then transferred to the path 24 by the center robot CR (see an arrow c in FIG. 12).

Step S6: The cleaned substrate W having been subjected to the cleaning processing is transferred by the return hand 11b. To begin with, the height of the reference position of the return hand 11b and the depth by which the return hand 11b is advanced into the carrier C are determined on the basis of the substrate information. In other words, parameters related to the control of the return hand 11b are changed in such a manner that the return hand 11b performs the determined operation. Specifically, this step is implemented as a fine adjustment of the reference transfer operation of the return hand 11b.

As the substrate information related to the fine adjustment of the return hand 11b, it is possible to use the substrate information that is the same as that related to the fine adjustment of the pickup hand 11a. Each of the substrates W having been held in the carrier C is returned, after the substrate processing, in the same order in the carrier C. Therefore, the same height and the same advancement depth are used in causing the return hand 11b to return the substrate W into the carrier C, as those used by the pickup hand 11a in picking up the substrates W from the carrier C. The height and the advancement depth of the pickup hand 11a are values unique to each of the substrates W held in the carrier C. In the process of returning the substrate W to the carrier C, the operation of the pickup hand 11a is reproduced by the return hand 11b, on the basis of these unique values. In this manner, the tip of the return hand 11b is also prevented from colliding with the substrate W in the process of returning the substrate W.

Step S7: The return hand 11b picks up the substrate W to be transferred from the path 24. The arm 12 of the indexer robot IR is moved in the vertical direction, and positions the return hand 11b at the height determined in step S6. To carry the substrate W into the carrier C, the return hand 11b is moved forwards by the same amount, as that by which the pickup hand 11a is moved when the pickup hand 11a has picked up the substrate W from the carrier C. The return hand 11b having placed the substrate W on the carrier C and returning to the substrate transfer apparatus is at the same height as that when the pickup hand 11a picks up the substrate W from the carrier C. This is because the pickup hand 11a and the return hand 11b operate on the basis of the common fine adjustment. The return hand 11b transfers the substrate W to be transferred from the path 24 to the carrier C (see an arrow d in FIG. 12). The substrate W having been resting on a certain protrusion in the comb-like member 7 of the carrier C is returned to the same protrusion through the substrate pick-up operation and the substrate return operation.

Step S8: Upon completing returning the substrate W into the carrier C, the substrate transfer apparatus repeats the mapping operation of the substrate W as in step S1. As a result, the operation of the substrate transfer apparatus according to this example is ended.

Note that the above description of the operations from step S1 to step S8 has focused on one substrate W. Therefore, in a case where a plurality of substrates W are to be transferred from the carrier C and the cleaning process of the substrates W to be performed, steps S3 and S4 may be repeated before the system control goes to step S5. In the same manner, steps S6 and S7 may be repeated before the system goes to step S9.

### 8. Effects Achieved by Embodiment 1

As described above, the substrate transfer apparatus described above receives substrate information corresponding to each of the substrates W held in the carrier C. The substrate information includes information corresponding to each of the substrate. The substrate transfer apparatus described above changes the transfer operation of the pickup hand 11a, for each of the substrates W, on the basis of the substrate information. With this configuration, even when different types of substrates W are stored in the carrier C, the pickup hand 11a can be controlled appropriately, on the basis of the substrate information. As a result, it becomes possible to transfer the substrate W using a transfer operation suitable for the substrate W, on the basis of the substrate information.

With the configuration described above, the substrate transfer apparatus stores therein the reference transfer operation of the pickup hand 11a. By editing the reference transfer operation of the pickup hand 11a, the transfer operation of the pickup hand 11a is changed to an appropriate one. With this configuration, the transfer operation of the pickup hand 11a can be changed easily and reliably.

With the configuration described above, different substrate information is used for each of the substrates W held in the carrier C, for example. With this configuration, even when different types of substrates W are stored in one carrier C, each of the substrates W can be transferred reliably.

With the configuration described above, the substrate information includes information related to a substrate diameter, for example. The pickup hand 11a transfers the substrate W using a transfer operation by which the position of the guide member 32 is matched to the position of the peripheral portion of the substrate W to be transferred. With this configuration, even when substrates W with different diameters are stored inside a single carrier C, each of the substrates W can be transferred reliably.

With the configuration described above, the substrate information includes information related to a substrate thickness, for example. The position, in the vertical direction, at which the pickup hand 11a is advanced into the carrier C is set for each of the substrates W, on the basis of the substrate information. With this configuration, even when a thick substrate W is being held in the carrier C, the pickup hand 11a does not damage the substrate W by coming into contact with the substrate W.

With the configuration described above, the substrate information includes information related to a substrate shape, for example. The position, in the vertical direction, at which the pickup hand 11a is advanced into the carrier C is set for each of the substrates W, on the basis of the substrate information. With this configuration, even when substrates W having different shapes are held in the carrier C, the pickup hand 11a does not damage the substrate W by coming into contact with the substrate W.

With the configuration described above, the substrate information includes an evaluation value indicating the amount of deformation of the substrate W and the direction of the deformation of the substrate W. With this configuration, even when a warped substrate W is held in the carrier C, the pickup hand 11a does not damage the substrate W by coming into contact with the substrate W.

With the configuration described above, the substrate information includes information related to the pitch of the substrates W stored in the carrier C. The position, in the vertical direction Z, at which the pickup hand 11a is advanced into the carrier Cis then set for each of the substrates W, on the basis of the substrate information. With this configuration, because the transfer operation of the pickup hand 11a is changed on the basis of information other than the information related to the substrate W itself, it is possible to transfer the substrate W appropriately, on the basis of a larger amount of information.

### Embodiment 2

### 9. Outline of Embodiment 2

Embodiment 2 relates to a substrate transfer apparatus, but in the explanation below, an example of a substrate processing apparatus 1 having the substrate transfer apparatus incorporated therein will be used as an example, in the same manner as in Embodiment 1. As described with reference to FIG. 1, the substrate processing apparatus 1 according to Embodiment 2 includes the load port 10, the indexer block 3, and the processing block 5. In the substrate transfer apparatus according to this example, the indexer robot IR in the indexer block 3 has a different configuration from that in Embodiment 1.

### 10. Configuration of Indexer Robot

FIG. 13 schematically illustrates tip ends involved in holding of a substrate, in the indexer robot IR. The indexer robot IR includes a first pickup hand 51a, a first return hand 51b, a second pickup hand 61a, and a second return hand 61b. The arm 13 holds the first pickup hand 51a, the first return hand 51b, the second pickup hand 61a, and the second return hand 61b on top of one another in the vertical direction Z. The arm 13 can advance and retract the first pickup hand 51a, the first return hand 51b, the second pickup hand 61a, and the second return hand 61b, independently in the front-back direction X. In the configuration illustrated in FIG. 13, the second return hand 61b, the second pickup hand 61a, the first return hand 51b, and the first pickup hand 51a are arranged from the top to the bottom, in the order listed herein, but the order in which these members are arranged may be changed as appropriate.

The first pickup hand 51a corresponds to the first hand according to the present invention, and corresponds to the pickup hand 11a in Embodiment 1. The first pickup hand 51a therefore holds one unprocessed substrate W at a time from the carrier C, and transfers the substrate W onto the path 24. The first pickup hand 51a includes a hand body 53 and a first guide member 52. The first guide member 52 is positioned at the tip end of the first pickup hand 51a, and is configured to abut against the end of the substrate W. The hand body 53 has the same configuration as the hand body 31 according to Embodiment 1. The first guide member 52 has the same configuration as the guide member 32 according to Embodiment 1. The first guide member 52 therefore has a thick portion and a thin portion. The first guide member 52 has parts with different thicknesses in the height direction. The first pickup hand 51a is a hand that transfers one substrates W at a time, from the carrier C that stores therein a plurality of substrates W in the horizontal postures, with a wider interval therebetween in the vertical direction Z. Specifically, the wider interval herein is 20 mm.

The first return hand 51b corresponds to the return hand 11b according to Embodiment 1, and has the same configuration as the first pickup hand 51a described above. The first pickup hand 51a is a hand for picking up the unprocessed substrate W from the carrier C, and the first return hand 51b is a hand for returning the cleaned substrate W to the carrier C.

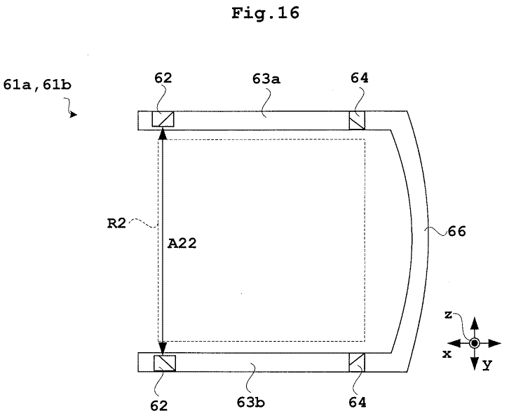

The second pickup hand 61a corresponds to a second hand according to the present invention. The second pickup hand 61a holds one unprocessed substrate W at a time from the carrier C, and transfers the substrate W onto the path 24. The first pickup hand 51a and the second pickup hand 61a have similar functions, but have different shapes (see FIGS. 15 and 16). The second pickup hand 61a includes a hand body 63 and a second guide member 62. The hand body 63 has a flat shape so as to be able to advance into the space between the substrates. The second guide member 62 is positioned at the tip end of the second pickup hand 61a, and is configured to abut against the end of the substrate W. The second guide member 62 is a tab provided at the tip end of the hand body 63, and is a member that comes into contact with the substrate W. The second guide member 62 is provided on the top surface of the hand body 63. The second guide member 62 has a thick portion and a thin portion, in the same manner as the first guide member 52 described above. The second guide member 62 thus has parts with different thicknesses in the height direction. A wall of the thick portion of the second guide member 62, the wall facing the base end of the second pickup hand 61a, can come into contact with the peripheral end (bevel portion) of the substrate W. A flat part facing upwards in the thin portion of the second guide member 62 can come into contact with the peripheral portion of the bottom surface of the substrate. The guide member is also provided at the base end of the hand body 63 (not illustrated in FIG. 13). The guide member form a contact portion that comes into contact with the substrate W in the second pickup hand 61a. The second pickup hand 61a is a hand that transfers one substrates W at a time, from the carrier C that stores therein a plurality of substrates W in the horizontal postures, at a narrower interval therebetween in the vertical direction Z. Specifically, the narrower interval herein is 10 mm.

The second return hand 61b has the same configuration as the second pickup hand 61a described above. In other words, the second return hand 61b includes the hand body 63 and the second guide member 62. The second return hand 61b and the second pickup hand 61a share the same configuration in which the second guide members 62 are provided at the tip end and the base end of the hand body 63, respectively, and each of the second guide member 62 has a thick portion and a thin portion. The second return hand 61b according to this example is provided to transfer the cleaned substrate W. By using different hands in a path for moving forwards and a path for moving rearwards in the operation of moving the substrate W back and forth, it is not necessary to use a hand having held an uncleaned substrate W in holding a cleaned substrate W. By providing the second return hand 61b, the cleanliness of the cleaned substrate W can be maintained.

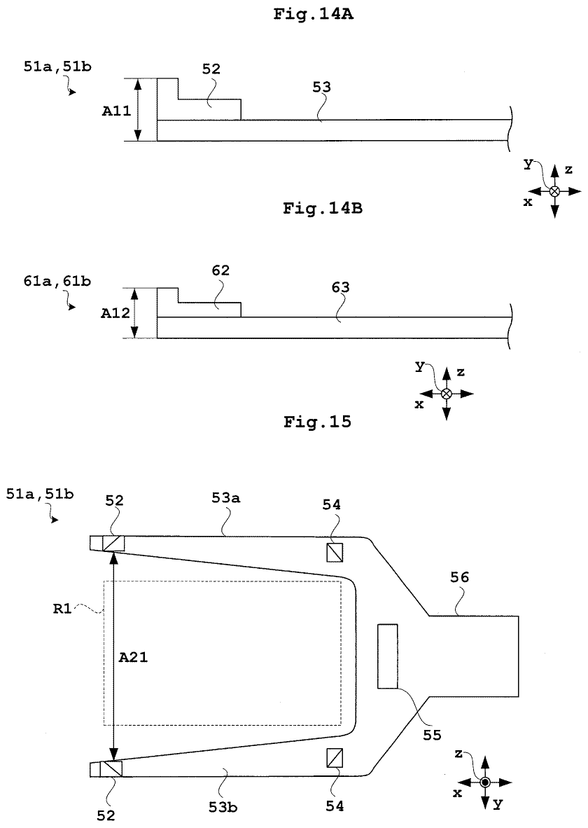

FIG. 14A illustrates the tip end of the first pickup hand 51a and the first return hand 51b, and FIG. 14B illustrates the tip end of the second pickup hand 61a or the second return hand 61b. The thickness A11 of the tip end of the first pickup hand 51a and the first return hand 51b in the vertical direction Z corresponds to a distance between the top end of the thick portion of the first guide member 52 and the bottom end of the hand body 53. In the same manner, the thickness A12 of the tip end of the second pickup hand 61a or the second return hand 61b in the vertical direction Z at corresponds to a distance between the top end of the thick portion of the second guide member 62 and the bottom end of the hand body 63. The thickness A12 of the tip end of the second pickup hand 61a and the second return hand 61b in the height direction is smaller than the thickness A11 of the tip end of the first pickup hand 51a and the first return hand 51b in the height direction. Therefore, the second pickup hand 61a and the second return hand 61b can advance into a gap smaller than that the first pickup hand 51a and the first return hand 51b. Such a configuration is advantageous when the pitch of the substrates W is small, and the substrates are close to each other. By contrast, the first pickup hand 51a and the first return hand 51b are capable of transferring substrates heavier than those the second pickup hand 61a and the second return hand 61b are capable of transferring. This point will be described later.

FIG. 15 is a plan view for explaining the first pickup hand 51a and the first return hand 51b. The first pickup hand 51a and the first return hand 51b have the same configurations as the pickup hand 11a and the return hand 11b according to Embodiment 1. In other words, each of the first pickup hand 51a and the first return hand 51b includes a base end 56, and a first holding body 53a and a second holding body 53b that are branched out from the base end 56. Each of the first pickup hand 51a and the first return hand 51b includes a first holding body 53a that holds one end of the substrate W and extends in the front-back direction X, and a second holding body 53b that holds the other end of the substrate W and extends in the front-back direction X. The first guide members 52 are provided at the tip ends of the first holding body 53a and the second holding body 53b, respectively.

Guide members 54 are provided at the base ends of the first holding body 53a and the second holding body 53b, respectively. In the same manner as the first guide members 52 described above, each of the guide members 54 includes a thick portion having a wall with which the end (bevel portion) of the substrate W can come into contact, and a thin portion having a flat portion with which the peripheral portion of the bottom of the substrate can come into contact. The thick portion of the guide member 54 has the same thickness as the thick portion of the first guide member 52. The thin portion of the guide member 54 has the same thickness as the thin portion of the first guide member 52. The walls of the first guide members 52 and the guide members 54 are provided at positions belonging to a virtual circle that is slightly larger than the substrate W. As a result, the substrate W can fit inside the area for receiving the substrate W, the area being delineated by the thin portions of the first guide members 52 and the guide members 54.

Each of the first pickup hand 51a and the first return hand 51b have a pusher 55. The pusher 55 is provided to the tip end of the base end 56, and can push the substrate W held by the first guide members 52 and the guide member 54 in the frontward direction. The pusher 55 is enabled to open by moving rearwards, and to close by moving in the frontward direction. In order for the first holding body 53a and the second holding body 53b to hold the substrate W, to begin with, the first guide members 52 and the guide members 54 are caused to hold the substrate W, with the pusher 55 opened. The pusher 55 is then closed, so as to nip the substrate W between the first guide members 52 and the pusher 55. The substrate W is gripped in the manner described above. By contrast, neither the second pickup hand 61a nor the second return hand 61b has a pusher. Therefore, the second guide member 62 and the guide member 64 of the second pickup hand 61a, which will be described later, have a clearance with respect to the substrate W to be held. The second pickup hand 61a transfers the substrate W with the clearance ensured. The same applies to the second return hand 61b.

FIG. 16 is a plan view for explaining the second pickup hand 61a and the second return hand 61b. Each of the second pickup hand 61a and the second return hand 61b includes a base end 66, and a first blade 63a and a second blade 63b that are branched out from the base end 66. Each of the second pickup hand 61a and the second return hand 61b includes the first blade 63a that holds one end of the substrate W and extends in the front-back direction X, and the second blade 63b that holds the other end of the substrate W and extends in the front-back direction X. The second guide member 62 is provided at the tip end of each of the first blade 63a and the second blade 63b.

Guide members 64 are provided at the base ends of the first blade 63a and the second blade 63b, respectively. In the same manner as the guide members 54 described above, each of the guide member 64 includes a thick portion having a wall with which the end (bevel portion) of the substrate W can come into contact, and a thin portion having a flat portion with which the peripheral portion of the bottom of the substrate can come into contact. The thick portion of the guide member 64 has the same thickness as the thick portion of the second guide member 62. The thin portion of the guide member 64 has the same thickness as the thin portion of the second guide member 62. The walls of the second guide members 62 and the guide members 64 are provided at positions belonging to a virtual circle that is slightly larger than the substrate W. As a result, the substrate W can fit inside the area for receiving the substrate W, the area being delineated by the thin portions of the second guide members 62 and the guide members 64.

The first pickup hand 51a and the second pickup hand 61a have shapes that are different from each other. In other words, as can be seen with reference to FIG. 15, each of the first holding body 53a and the second holding body 53b of the first pickup hand 51a has a tapered shape in which the thickness in the width direction Y increases from the tip end toward the base end. With such a configuration, the rigidity of the first pickup hand 51a is increased, and heavier substrates can be transferred. An example of the heavier substrate W is a thick substrate formed by bonding two substrates. The same kind of effect can also be achieved by the first return hand 51b. Thick substrates W can be stored in the carrier C at a pitch of 20 mm.

By contrast, as can be seen with reference to FIG. 16, each of the first blade 63a and the second blade 63b included in the second pickup hand 61a have a constant thickness in the width direction Y, across the tip end toward the base end. With such a configuration, a wider space R2 can be ensured between the first blade 63a and the second blade 63b. Although a space R1 is ensured between the first holding body 53a and the second holding body 53b in the first pickup hand 51a illustrated in FIG. 15, the space R1 is smaller than the space R2, because the first holding body 53a and the second holding body 53b are tapered. The space between the first holding body 53a and the second holding body 53b is smaller than the space between the first blade 63a and the second blade 63b.

As can be seen with reference to FIG. 16, the distance A22 by which the first blade 63a and the second blade 63b of the second pickup hand 61a are separated is made as large as possible. With a wider space R2 ensured, the second pickup hand 61a can transfer a substrate W that is difficult to transfer, reliably. The substrate W that is difficult to transfer is, specifically, a warped substrate W. A warped substrate W is sometimes deformed in a shape recessed toward the center of the substrate W, and the warped substrate W is therefore more likely to come into contact with the hand, at the time of transfer. In this regard, the second pickup hand 61a has a configuration in which the first blade 63a and the second blade 63b are not provided to the parts where the warped substrate may come into contact. Therefore, the second pickup hand 61a according to this example can transfer the substrate W that is more difficult to transfer, reliably.

A separation distance A21 is a distance between the first guide member 52 provided on the first holding body 53a and the first guide member 52 provided on the second holding body 53b. A separation distance A22 is a distance between the second guide member 62 provided on the first blade 63a and the second guide member 62 provided on the second blade 63b.

Meanwhile, the first guide member 52 in the first pickup hand 51a has a thick portion and a thin portion, as can be seen with reference to FIG. 14A. In the same manner, the second guide member 62 on the second pickup hand 61a has a thick portion and a thin portion, as can be seen with reference to FIG. 14B. The thin portion of the first guide member 52 has a thickness thicker than the thin portion of the second guide member 62. With this configuration, separation of the substrate W to be transferred from the hand body 53 can be ensured. It is assumed herein that the substrate W held by the first pickup hand 51a is warped, and has a recess at the center of the substrate W. Even in such a case, because the thin portion of the first guide member 52 has a sufficient thickness, the central part of the substrate W does not come into contact with the hand bodies 53 of the first pickup hand 51a. The first pickup hand 51a is also capable of transferring a substrate W warped to such an extent that the second pickup hand 61a cannot transfer the substrate W. The substrate W with such an extensive warpage can be stored in the carrier C at a pitch of 20 mm.

When the thickness of the first guide member 52 is increased, the thickness of the first pickup hand 51a is also increased, accordingly. However, because the first pickup hand 51a is used for the carrier C with a larger pitch of the substrates W, there is less restriction on the thickness of the first pickup hand 51a. Therefore, even when the thickness of the first pickup hand 51a is sufficiently increased, the first pickup hand 51a does not come into contact with the substrate W to be transferred and the substrate W below the substrate W to be transferred. The same kind of effect can also be achieved by the second return hand 61b.

When the indexer robot IR transfers the substrate W in the carrier C onto the path 24, the indexer robot IR uses either the first pickup hand 51a or the second pickup hand 61a. The first pickup hand 51a or the second pickup hand 61a is advanced between the first substrate W1 that is the substrate to be transferred, and the second substrate W2 positioned below the first substrate W1 held in the carrier C, and is then raised to pick up the first substrate W1. The first substrate W1 thus picked up is transferred onto the path 24.

When the indexer robot IR transfers the substrate W on the path 24 into the carrier C, the indexer robot IR uses either the first return hand 51b or the second return hand 61b. The first return hand 51b or the second return hand 61b picks up the substrate W to be transferred held on the path 24, and is advanced into the carrier C. The first return hand 51b or the second return hand 61b is then lowered, to place the substrate W to be transferred on the carrier C. The first return hand 51b or the second return hand 61b is retracted by moving between the substrate W having been transferred and the substrate W positioned below the transferred substrate W, and is moved away from the carrier C.

### 11. Other Configurations

One example of the control related to the control unit 100 illustrated in FIG. 1 includes control related to the indexer robot IR. In other words, the control unit 100 controls the operation of advancing and retracting the first pickup hand 51a, the first return hand 51b, the second pickup hand 61a, and the second return hand 61b, the operation of opening and closing the pusher 55, the movement of the arm 13 in the vertical direction Z, a mapping sensor, to be described later, and an actuator mechanism for the mapping sensor. The control unit 100 also makes a selection as to which one of the four types of hands is to be used in the transfer. The storage unit 101 and the input/output device 102 have the same configurations as those according to Embodiment 1.

### 12. Sequence of Substrate Transfer

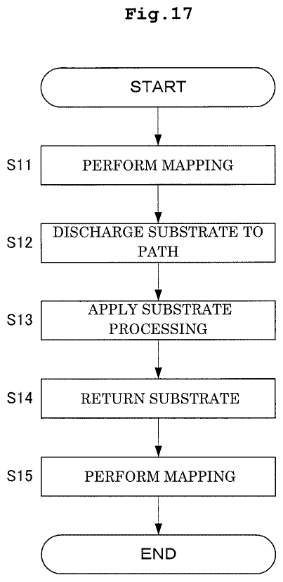

FIG. 17 is a flowchart of an operation for explaining the substrate transfer apparatus according to the present invention. An operation of the substrate transfer apparatus performed when the substrate processing apparatus 1 according to the present invention performs a substrate cleaning process will now be described. FIG. 12 illustrates how the substrate W is transferred inside the substrate processing apparatus 1. In the following description, FIG. 12 is also referred to, as appropriate.

Step S11: When the carrier C to be processed is placed at the load port 10, the substrate transfer apparatus starts the mapping operation of the substrate W. Because this step is the same as step S1 in Embodiment 1, detailed description thereof will be omitted.

With this step, it becomes possible to recognize how the comb-like member 7 of the carrier C holds the substrate W. The comb-like member 7 has twenty five protrusions, each of which is capable of holding a substrate W. For example, thirteen substrates W may be stored at a pitch of 20 mm in the carrier C. As another example, twenty five substrates W may be stored a pitch of 10 mm in the carrier C. In order to recognize which one of the pitches at which the substrates W are arranged, the mapping operation may be performed. Note that the substrate transfer apparatus can also recognize the pitch of the substrates W on the basis of the substrate information obtained from the host computer 200. For the details of acquiring the substrate information via the host computer 200, a reference to step S1 described above may be made.

In the operation described with reference to FIG. 17, when the distance between the substrates is 20 mm and therefore has extra room for the hand to advance, the first pickup hand 51a and the first return hand 51b are used in transferring the substrate. By contrast, the second pickup hand 61a and the second return hand 61b are used in transferring the substrate when the distance between the substrates is 10 mm and therefore has no extra room for the hand to advance.

Step S12: The indexer robot IR is moved toward the back of the carrier C. The arm 13 of the indexer robot IR is then moved in the vertical direction. When the pitch of the substrates W is 20 mm, the first pickup hand 51a is carried to the height of the substrate W to be transferred. The first pickup hand 51a is then caused to grip the substrate W to be transferred, and to discharge the substrate W onto the path 24 (see the arrow a in FIG. 12). By contrast, when the pitch of the substrates W is 10 mm, the second pickup hand 61a is carried to the height of the substrate W to be transferred. The second pickup hand 61a is then caused to hold the substrate W to be transferred, and to discharge the substrate W to the path 24.

Step S13: The unprocessed substrate W held on the path 24 is transferred to the single-wafer processing chamber 5a by the center robot CR (see an arrow b in FIG. 12). The single-wafer processing chamber 5a performs cleaning processing on the substrate W. The processed substrate W is then transferred to the path 24 by the center robot CR (see an arrow c in FIG. 12).

Step S14: The cleaned substrate W having been subjected to the cleaning processing is transferred either by the first return hand 51b or the second return hand 61b. The substrate W having been transferred to the path 24 using the first pickup hand 51a in step S12 is returned from the path 24 to the carrier C using the first return hand 51b. At this time, the substrate W is transferred at a high speed. The substrate W having been transferred to the path 24 using the second pickup hand 61a in step S12 is returned from the path 24 to the carrier C using the second return hand 61b (see the arrow d in FIG. 12). The substrate W having been resting on a certain protrusion in the comb-like member 7 of the carrier C is returned to the same protrusion through the substrate pick-up operation and the substrate return operation.

Step S15: Upon completing returning the substrate W to the carrier C, the substrate transfer apparatus repeats the mapping operation of the substrate W as in step S11. As a result, the operation of the substrate transfer apparatus according to this example is ended.

Note that the above description of the operations from step S1 to step S15 has focused on one substrate W. Therefore, in a case where a plurality of substrates W are to be transferred from the carrier C and the cleaning process of the substrates W is to be performed, step S12 may be repeated before the system control goes to step S13. In the same manner, step S14 may be repeated before the system goes to step S15.

### 13. Effects Achieved by Embodiment 2

The substrate transfer apparatus according to this example includes two types of hands, that is, the first pickup hand 51a and the first return hand 51b, and the second pickup hand 61a and the second return hand 61b, and includes the control unit 100 that uses the first pickup hand 51a and the first return hand 51b, and the second pickup hand 61a and the second return hand 61b, selectively, to transfer the substrate W. With such a configuration, when the pitch of the substrates W is larger, it is possible to use the first pickup hand 51a and the first return hand 51b to transfer the substrates W. When the pitch of the substrates W is small, it is possible to use the second pickup hand 61a and the second return hand 61b to transfer the substrates W. In other words, with the substrate transfer apparatus according to the present invention, it is possible to transfer the substrates W using a method more suitable for the actual substrates W stored in the carrier C.

Furthermore, according to this example, the thickness A12 of the tip end of the second pickup hand 61a and the second return hand 61b in the height direction is smaller than the thickness A11 of the tip end of the first pickup hand 51a and the first return hand 51b in the height direction. With this configuration, by using the second pickup hand 61a and the second return hand 61b, even when the substrate W is warped extensively and the distance between the substrates is small, it is possible to transfer the substrate W to be transferred more reliably.

According to this example, the space R1 between the first holding body 53a and the second holding body 53b in the first pickup hand 51a and the first return hand 51b is smaller than the space R2 between the first blade 63a and the second blade 63b in the second pickup hand 61a or the second return hand 61b. With this configuration, the first pickup hand 51a and the first return hand 51b can hold the substrate W more reliably. By contrast, the second pickup hand 61a and the second return hand 61b can hold the substrate W between the first blade 63a and the second blade 63b, reliably.

According to this example, each of the first pickup hand 51a and the first return hand 51b have the pusher 55 for gripping the substrate W. As a result, the first pickup hand 51a and the first return hand 51b can hold and transfer the substrate W reliably. Neither the second pickup hand 61a nor the second return hand 61b has a pusher. With this configuration, it is possible to simplify the structure of the apparatus, and to reduce the thickness of the second pickup hand 61a and the second return hand 61b in the height direction.

### 14. Modifications of Present Invention

The present invention is not limited to the configurations described above, and following modifications are still possible.

### <Modification 1>

The mapping unit 84 according to Embodiment 1 may set a detection threshold, on the basis of the substrate information related to the substrate thickness. In other words, when the substrates W stored in the carrier C are thin, the detection threshold may be lowered before causing the mapping unit 84 to operate. In this manner, it is possible to prevent overlooking of the thin substrates W, and skipping the mapping operation. When the substrates W stored in the carrier C are thick, the detection threshold may be raised before causing the mapping unit 84 to operate. In this manner, it is possible to suppress malfunctioning of the mapping unit 84 due to noise.

According to this modification, the substrate information includes information related to a substrate thickness, for example. The mapping unit 84 has a detection threshold appropriate for the thickness of the substrate. With the configuration described above, because the detection threshold is set on the basis of the substrate information, it is possible to performing the mapping of the substrate W, on the basis of a detection threshold that is suitable for the mapping.

### <Modification 2>

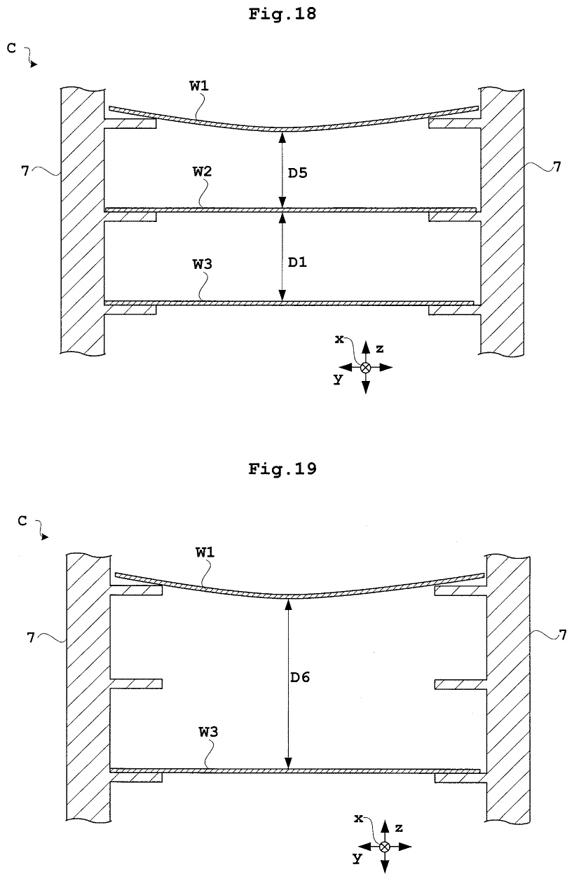

The order in which the substrates W in the carrier C are transferred may be set on the basis of the substrate information according to Embodiment 1. FIG. 18 illustrates an arrangement in which the first substrate W1 warped downwards and the second substrate W2 below the first substrate W1 are placed on the comb-like member 7 of the carrier C. The third substrate W3 is located further below the second substrate W2 in the comb-like member 7. The first substrate W1, the second substrate W2, and the third substrate W3 are arranged at a pitch of 10 mm. Therefore, the second pickup hand 61a and the second return hand 61b are used in transferring the substrates W. In the case of this modification, the distance D5 by which the first substrate W1 and the second substrate W2 are separated is too short for the second pickup hand 61a. Therefore, the transfer of the first substrate W1 is obstructed by the second substrate W2. The warpage of the first substrate W1 can be recognized, by referring to the substrate information.

It is assumed that the distance between the second substrate W2 and the third substrate W3 is D1. The distance D1 is sufficient for the second pickup hand 61a and the second return hand 61b to advance into the space between the second substrate W2 and the third substrate W3. Therefore, it is possible to transfer the second substrate W2 from the carrier C, regardless of whether the third substrate W3 is present.

Therefore, this modification is configured to set the order in which the substrates W are transferred, on the basis of the substrate information related to the substrate shape. In other words, the control unit 100 sets the order in which the substrates W are transferred so that the second substrate W2 is transferred before the first substrate W1.

FIG. 19 illustrates the carrier C after the second substrate W2 has been transferred from the carrier C. After the second substrate W2 has been transferred, there are the first substrate W1 and the third substrate W3 in the carrier C. Between the first substrate W1 and the third substrate W3, there is a vacant protrusion on the comb-like member 7. Therefore, the distance D6 between the first substrate W1 and the third substrate W3 is larger than at least the distance D1. In other words, the pickup hand 11a and the return hand 11b can advance into the space between the first substrate W1 and the third substrate W3. Therefore, even in the carrier C in the condition as illustrated in FIG. 18, by transferring the second substrate W2 and the first substrate W1, in the order listed herein, the first substrate W1 can be transferred from the carrier C, reliably. When these substrates W is to be returned to the carrier C, the first substrate W1 and the second substrate W2 may be transferred in the order listed herein.

With the configuration described above, the substrate information includes information related to a substrate shape, for example. The order in which the substrates W in the carrier C are transferred is set on the basis of the substrate information. As a result, it becomes possible to transfer the substrates W that cannot be transferred in a particular order, reliably.

### <Modification 3>

The transfer speeds of the pickup hand 11a and the return hand 11b may be set on the basis of the substrate information according to Embodiment 1. For example, the substrate transfer apparatus according to this modification transfers a flat substrate W at a higher speed, and transfers a warped substrate W at a lower speed, on the basis of the substrate information related to the substrate shape. With the configuration described above, the transfer speeds of the pickup hand 11a and the return hand 11b are set on the basis of the substrate information. With this configuration, the substrates can be transferred at transfer speeds appropriate thereto, depending on the substrates W. This modification is also applicable to Embodiment 2.

### <Modification 4>

It is also possible to provide carrier information related to the type of the carrier C, in addition to the substrate information according to Embodiment 1. The input/output device 102 according to this modification receives the carrier information corresponding to a carrier from the host computer 200. The carrier information includes, for example, information related to the pitch of the protrusions 7a of the comb-like member 7. The substrate transfer apparatus according to this modification can operate using carrier information, instead of substrate information related to the pitch of the substrates W. In other words, the substrate transfer apparatus according to this modification changes the transfer operations of the pickup hand 11a and the return hand 11b for each carrier C, on the basis of the carrier information. Specifically, the position, in the vertical direction, at which the pickup hand 11a is advanced into the carrier C is set on the basis of the carrier information. With the configuration described above, the substrate transfer apparatus receives the carrier information corresponding to the carrier C. The transfer operations of the pickup hand 11a and the return hand 11b are then changed for each of the carriers C, on the basis of the carrier information. With this configuration, the transfer operations of the pickup hand 11a and the return hand 11b can be changed for all of the substrates, in the unit of one carrier. The carrier information may include information other than information related to the carrier type, such as a substrate diameter. This modification is also applicable to Embodiment 2. Specifically, the type of the hand used for the transfer is determined on the basis of the carrier information. When the pitch of the protrusions 7a is 20 mm, the first pickup hand 51a and the first return hand 51b are used for the transfer of the substrates. When the pitch of the protrusions 7a is 10 mm, the second pickup hand 61a and the second return hand 61b are used for the transfer of the substrates.

### <Modification 5>

In the substrate transfer apparatus according to Embodiment 1, the mapping operation described in step S1 may be omitted. This is because the substrate transfer apparatus can recognize how the substrates W are stored in the carrier C from the substrate information related to the pitch of the substrates W.

### <Modification 6>

In the configuration according to Modification 5, the mapping operation may be performed when a predetermined condition is satisfied. In other words, the substrate transfer apparatus according to this modification may cause the mapping unit 84 to execute the mapping operation at least when the pitch of the protrusions 7a included in the carrier information described in Modification 4 does not match the pitch of the substrates W stored in the carrier C in the substrate information. According to this modification, the mapping operation is performed to measure the actual pitch of the substrates W in the carrier C. The substrate transfer apparatus operates by prioritizing the result of the actual measurement, over carrier information and substrate information. In other words, the transfer operations of the pickup hand 11a and the return hand 11b are changed on the basis of the result of the mapping operation. According to this modification, even when there is an error in one of the carrier information or the substrate information, the error is corrected before the substrate W is transferred.

### <Modification 7>

In the configuration according to Modification 5, the mapping operation may be performed when a predetermined condition is satisfied. In other words, the substrate transfer apparatus according to this modification may cause the mapping unit 84 to execute the mapping operation at least when the pitch of the protrusions 7a in the carrier information described in Modification 4 is 20 mm. According to this modification, the mapping operation is performed to measure the actual pitch of the substrates W in the carrier C. The substrate transfer apparatus operates by prioritizing the result of the actual measurement over carrier information. In other words, the transfer operations of the pickup hand 11a and the return hand 11b are changed on the basis of the result of the mapping operation. According to this modification, even when there is an error in the carrier information, the error is corrected before the substrate W is transferred. Note that the pitch for which the mapping operation is performed is not limited to 20 mm, and may be sat equal to or larger than 20 mm, for example.

### <Modification 8>

In the substrate transfer apparatus according to Embodiment 2, the hand body 53 of the first pickup hand 51a may be configured to be thicker than the hand body 63 of the second pickup hand 61a. With this configuration, the rigidity of the first pickup hand 51a is increased, so that the substrate W can be more transferred reliably. The same applies to the first return hand 51b.

### <Modification 9>

In the substrate transfer apparatus according to Embodiment 2, the substrates may be transferred using the second pickup hand 61a, in replacement of the first pickup hand 51a. With this configuration, even when there is a failure in the first pickup hand 51a, it is possible to operate the substrate transfer apparatus. The same applies to the second return hand 61b.

What is claimed is:

1. A substrate transfer apparatus comprising:
a hand that holds and transfers a plurality of substrates one by one from a carrier that stores the substrates in horizontal postures, with a predetermined interval between the substrates in a vertical direction;
a receiving unit that receives substrate information corresponding to each of the substrates held in the carrier; and
a control unit that controls the hand, wherein
the control unit is enabled to change a transfer operation of the hand, for each of the substrates, based on the substrate information.

2. The substrate transfer apparatus according to claim 1, further comprising a storage unit that stores a reference transfer operation of the hand, and
the control unit changes the transfer operation of the hand by changing an amount by which the hand is moved, the amount being an amount that defines the reference transfer operation of the hand.

3. The substrate transfer apparatus according to claim 1, wherein the substrate information includes a different piece of information for each of the substrates held in the carrier.

4. The substrate transfer apparatus according to claim 1, wherein
the substrate information includes information related to a substrate diameter,
the hand includes a guide member coming into contact with a peripheral portion of the substrate, and
the control unit changes the transfer operation of the hand in such a manner that a position of the guide member is matched to a position of the peripheral portion of the substrate to be transferred.

5. The substrate transfer apparatus according to claim 1, wherein
the substrate information includes information related to a substrate thickness, and
the control unit sets a position, in the vertical direction, at which the hand is advanced into the carrier, for each of the substrates, on the basis of the substrate information.

6. The substrate transfer apparatus according to claim 1, further comprising a mapping unit that performs mapping of a substrate in the carrier, wherein
the substrate information includes information related to a substrate thickness, and
the mapping unit sets a detection threshold based on the substrate information.

7. The substrate transfer apparatus according to claim 1, wherein
the substrate information includes information related to a substrate shape, and
the control unit sets a position, in the vertical direction, at which the hand is advanced into the carrier, for each of the substrates, on the basis of the substrate information.

8. The substrate transfer apparatus according to claim 7, wherein the information related to the substrate shape is an evaluation value indicating an amount of deformation of the substrate and a direction of the deformation of the substrate.

9. The substrate transfer apparatus according to claim 7, wherein the control unit sets an order in which the substrates inside the carrier are transferred, based on the substrate information.

10. The substrate transfer apparatus according to claim 1, wherein
the control unit sets a transfer speed of the hand based on the substrate information.

11. The substrate transfer apparatus according to claim 1, wherein
the substrate information includes information related to a pitch of substrates stored in the carrier, and
the control unit sets a position, in the vertical direction, at which the hand is advanced into the carrier, on the basis of the substrate information.

12. The substrate transfer apparatus according to claim 1, wherein
the receiving unit receives carrier information corresponding to the carrier, and
the control unit changes the transfer operation of the hand for each carrier, based on the carrier information received by the receiving unit.

13. The substrate transfer apparatus according to claim 12, wherein
a plurality of protrusions capable of holding a substrate are arranged inside the carrier in the vertical direction,
the carrier information includes information related to a pitch of the protrusions, and
the control unit sets a position, in the vertical direction, at which the hand is advanced into the carrier, based on the carrier information.

14. The substrate transfer apparatus according to claim 13, further comprising a mapping unit that performs mapping of a substrate in the carrier, wherein
the substrate information includes information related to a pitch of the substrates stored inside the carrier, and
the control unit causes the mapping unit to execute a mapping operation when at least the pitch of the protrusions, the pitch being a pitch in the carrier information, does not match the pitch of the substrates stored inside the carrier, the pitch being a pitch in the substrate information, and changes the transfer operation of the hand based on a result of the mapping operation.

15. The substrate transfer apparatus according to claim 13, further comprising a mapping unit that performs mapping of a substrate in the carrier, wherein
the control unit causes the mapping unit to execute a mapping operation at least when the pitch of the protrusions in the carrier information is equal to or larger than a predetermined value, and changes the transfer operation of the hand based on a result of the mapping operation.

16. A substrate processing apparatus comprising:
the substrate transfer apparatus according to claim 1; and
a substrate processing unit configured to perform predetermined processing on the substrate transferred by the substrate transfer apparatus.

17. A substrate processing system comprising:
the substrate processing apparatus according to claim 16; and
a host computer that transmits, to the substrate processing apparatus, substrate information corresponding to each of the substrates held in the carrier.
